(19) United States
(12) Patent Application Publication
(10) Pub. No.: US 2025/0301749 A1
(43) Pub. Date: Sep. 25, 2025

(54) Trench Semiconductor Structure and Manufacturing Method Thereof

(71) Applicant: Diodes Incorporated, Plano, TX (US)

(72) Inventors: Tachuan Kuo, New Taipei City (TW); Chiao-Shun Chuang, New Taipei City (TW)

(21) Appl. No.: 19/051,143

(22) Filed: Feb. 11, 2025

(30) Foreign Application Priority Data
Mar. 21, 2024 (CN) 202410325749.7

(51) Int. Cl. H10D 64/00; H10D 30/01; H10D 30/66; H10D 62/17; H10D 64/27; H10D 84/80

(52) U.S. Cl. CPC H10D 64/117; H10D 30/0297; H10D 30/668; H10D 62/393; H10D 64/513; H10D 84/811

(57) ABSTRACT

A trench semiconductor structure includes a semiconductor material layer of a first conductivity type and having a first surface and a second surface. A first trench structure extends from the first surface toward the second surface, and includes a first electrode, a first gate and a second electrode below the first electrode and the first gate. A first doped region of a second conductivity type is disposed in the semiconductor material layer. A second doped region of the first conductivity type is disposed between the first surface and the first doped region. An interlayer dielectric layer on the first surface covers the first trench structure and the second doped region. The first electrode is located between the first gate and the first doped region. The first electrode and the first doped region are electrically connected to a metal layer on the interlayer dielectric layer. A manufacturing method is also provided.

### CROSS-REFERENCE TO RELATED APPLICATIONS

This application claims priority to Chinese Patent Application No. 202410325749.7, filed on Mar. 21, 2024 and entitled “TRENCH SEMICONDUCTOR STRUCTURE AND MANUFACTURING METHOD THEREOF,” which is hereby incorporated by reference herein as if reproduced in its entirety.

### TECHNICAL FIELD

The present disclosure relates to a trench semiconductor structure and a manufacturing method thereof, and more particularly, to a rectifier device of a trench metal oxide semiconductor (MOS) structure and a manufacturing method thereof.

### BACKGROUND

Modern power circuits require rectifiers that provide high power, low power loss and fast switching. Known methods for integrating a super barrier rectifier (SBR) with a shielded gate trench metal oxide semiconductor field effect transistor (SGT MOSFET) involve designing a dedicated trench structure to set the SBR gate. The integration of the SBR with the SGTMOSFET can minimize the forward conduction voltage of the body diode, thereby reducing power loss. However, integrating the SBR with the SGT MOSFET increases cost, and further, placing the SBR and the SGT-MOSFET in adjacent areas of a same chip requires an additional chip area, which causes the need of further improvement in device miniaturization technology.

Since the forward conduction current of the SBR depends on its total width, any adjustment to increase or decrease this current requires a corresponding change in the trench gate width. Changes in the SGT MOSFET trench width limit design flexibility. Furthermore, a certain spacing is required between the SBR trench and the SGT MOSFET trench, resulting in wasted chip area and increased cost.

The current manufacturing methods and power circuit structures generally lack efficiency and flexibility, often resulting in waste of chip area, and thereby increasing production cost. Therefore, the semiconductor structures including rectifier devices in the art need to be further improved to obtain desired high power and low loss in order to improve device performance.

### SUMMARY

Technical advantages are generally achieved, by embodiments of this disclosure which describe trench semiconductor structures and manufacturing methods thereof.

Embodiments of the present disclosure relate to a trench semiconductor structure. The trench semiconductor structure includes: a semiconductor material layer having a first surface and a second surface opposite to the first surface, wherein the semiconductor material layer has a first conductivity type; a first trench structure extending from the first surface toward the second surface, wherein the first trench structure includes a first electrode, a first gate adjacent to the first electrode, a second electrode located below the first electrode and the first gate, and a first oxide layer separating the first electrode, the second electrode and the first gate from each other; a first doped region located in the semiconductor material layer adjacent to the first surface and adjacent to the first trench structure, wherein the first doped region has a second conductivity type; a second doped region located between the first surface and the first doped region, wherein the second doped region has the first conductivity type; an interlayer dielectric layer located on the first surface of the semiconductor material layer and covering the first trench structure and the second doped region; and a metal layer located on the interlayer dielectric layer. The first electrode is located between the first gate and the first doped region, and the first electrode and the first doped region are both electrically connected to the metal layer.

Embodiments of the present disclosure also relate to a trench semiconductor structure. The trench semiconductor structure includes: a semiconductor material layer, wherein the semiconductor material layer has a first conductivity type, and has a first region and a second region surrounding the first region; a first trench structure, recessed into the semiconductor material layer, and including a first electrode, a first gate, and a first oxide layer surrounding the first electrode and the first gate; a second trench structure, recessed into the semiconductor material layer, and including a second electrode, a second gate, and a second oxide layer surrounding the second electrode and the second gate; and a first doped region arranged in the semiconductor material layer and located between the first trench structure and the second trench structure, wherein the first doped region has the second conductivity type. The first electrode and the second electrode are arranged between the first gate and the second gate, the first electrode, the second electrode, and the first doped region between the first electrode and the second electrode are located in the first region, and the first gate and the second gate are located in the second region.

Embodiments of the present disclosure relate to a method for manufacturing a trench semiconductor structure. The method includes: forming a first trench in a semiconductor material layer, wherein the first trench and a second trench extend from a first surface toward a second surface; forming a first electrode and a second electrode located below the first electrode in the first trench; forming a first gate in the first trench, wherein the first gate is adjacent to the first electrode and located above the second electrode, and the first electrode, the second electrode and the first gate form a first trench structure; forming a first doped region in the semiconductor material layer, wherein the first doped region has a second conductivity type, and the first electrode is located between the first doped region and the first gate; forming a second doped region in the first doped region adjacent to the first surface of the semiconductor material layer, wherein the second doped region has a heavy doping of a first conductivity type; forming an interlayer dielectric layer on the first surface of the semiconductor material layer, wherein the interlayer dielectric layer covers the first trench structure and the second doped region; and forming a metal layer on the interlayer dielectric layer, wherein the first electrode and the first doped region are both electrically connected to the metal layer.

According to one aspect of the present disclosure, a trench semiconductor structure is provided that includes: a semiconductor material layer of a first conductivity type, the semiconductor material layer having a first surface and a second surface opposite to the first surface; a first trench structure extending from the first surface toward the second surface, wherein the first trench structure includes a first electrode, a first gate, a second electrode located below the first electrode and the first gate, and a first oxide layer separating the first electrode, the second electrode and the first gate from each other; a first doped region of a second conductivity type in the semiconductor material layer, wherein the first electrode is between the first gate and the first doped region; a second doped region of the first conductivity type, located between the first surface and the first doped region; and an interlayer dielectric layer over the first surface of the semiconductor material layer and covering the first trench structure and the second doped region; and a metal layer, located on the interlayer dielectric layer, wherein the first electrode and the first doped region are electrically connected to the metal layer.

According to another aspect of the present disclosure, a trench semiconductor structure is provided that includes: a semiconductor material layer of a first conductivity type, having a first region and a second region surrounding the first region; a first trench structure, recessed from a first surface of the semiconductor material layer into the semiconductor material layer, and comprising a first electrode, a first gate, and a first oxide layer surrounding and separating the first electrode and the first gate; a second trench structure, recessed from the first surface of the semiconductor material layer into the semiconductor material layer, and comprising a second electrode, a second gate, and a second oxide layer surrounding and separating the second electrode and the second gate; and a first doped region of a second conductivity type, disposed in the semiconductor material layer and between the first trench structure and the second trench structure; and wherein the first electrode and the second electrode are disposed between the first gate and the second gate, the first electrode, the second electrode, and the first doped region between the first electrode and the second electrode are located in the first region, and the first gate and the second gate are located in the second region.

According to another aspect of the present disclosure, a method of manufacturing a trench semiconductor structure is provided that includes: forming a first trench in a semiconductor material layer of a first conductivity type, wherein the first trench extends from a first surface of the semiconductor material layer toward a second surface of the semiconductor material layer opposite to the first surface; forming, in the first trench, a first electrode, a second electrode and a first gate, wherein the first gate and the first electrode are formed above the second electrode, and the first electrode, the second electrode and the first gate form a first trench structure; forming a first doped region of a second conductivity type in the semiconductor material layer, wherein the first electrode is located between the first doped region and the first gate; forming a second doped region of the first conductivity type in the first doped region and adjacent to the first surface of the semiconductor material layer, the second doped region being a heavily doped region; forming an interlayer dielectric layer over the first surface of the semiconductor material layer, wherein the interlayer dielectric layer covers the first trench structure and the second doped region; and forming a metal layer on the interlayer dielectric layer, wherein the first electrode and the first doped region are electrically connected to the metal layer.

### BRIEF DESCRIPTION OF THE DRAWINGS

Aspects of embodiments of the present disclosure may be better understood when the following detailed description is read in conjunction with the accompanying drawings. It should be noted that various structures may not be drawn to scale. In fact, the dimensions of various structures may be arbitrarily enlarged or reduced for clarity of discussion.

FIG. 1 is a top view of a trench semiconductor structure according to some embodiments of the present disclosure;

FIG. 2 is another top view of the trench semiconductor structure according to some embodiments of the present disclosure;

FIG. 3 is a cross-sectional view of the trench semiconductor structure shown in FIG. 1 or FIG. 2 along a line AA' according to some embodiments of the present disclosure;

FIG. 4 is another cross-sectional view of the trench semiconductor structure shown in FIG. 1 or FIG. 2 along the line AA' line according to some embodiments of the present disclosure;

FIG. 5 is a top view of another trench semiconductor structure according to some embodiments of the present disclosure;

FIG. 6 is another top view of the trench semiconductor structure of FIG. 5 according to some embodiments of the present disclosure;

FIG. 7 is a cross-sectional view of the trench semiconductor structure shown in FIG. 5 or FIG. 6 along a line BB' according to some embodiments of the present disclosure;

FIG. 8 is a top view of another trench semiconductor structure according to some embodiments of the present disclosure;

FIG. 9 is a top view of another trench semiconductor structure according to some embodiments of the present disclosure;

FIG. 10 is a top view of another trench semiconductor structure according to some embodiments of the present disclosure;

FIG. 11 is a top view of another trench semiconductor structure according to some embodiments of the present disclosure;

FIG. 12 is a top view of another trench semiconductor structure according to some embodiments of the present disclosure; and

FIG. 13 to FIG. 35 illustrate a trench semiconductor structure in one or more stages of a method for manufacturing the same according to some embodiments of the present disclosure.

The same or similar components are marked with the same reference numerals in the drawings and detailed description. Several embodiments of the present disclosure will be readily understood from the following detailed description in conjunction with the accompanying drawings.

### DETAILED DESCRIPTION OF ILLUSTRATIVE EMBODIMENTS

The following disclosure provides many different embodiments or examples for implementing the different features of the provided subject matter. Specific examples of components and configurations are described below. Certainly, these are only examples and are not intended to be limiting. In the present disclosure, references to forming a first feature above or on a second feature may include embodiments in which the first feature and the second feature are formed to be in direct contact, and may also include embodiments in which additional features may be formed between the first feature and the second feature so that the first feature and the second feature may not be in direct contact. In addition, the present disclosure may repeat reference numerals and/or letters in various examples. This repetition is for simplicity and clarity and does not itself indicate the relationship between the various embodiments and/or configurations discussed.

The following is a detailed discussion of embodiments of the present disclosure. However, it should be understood that the present disclosure provides various applicable concepts that may be embodied in a variety of specific environments. The specific embodiments discussed are merely illustrative and do not limit the scope of the present disclosure.

Embodiments of the present disclosure provides trench semiconductor structures and manufacturing methods thereof. In an embodiment trench semiconductor structure of the present disclosure, a super barrier rectifier (SBR) is integrated with a shielded gate trench metal oxide semiconductor field effect transistor (SGT MOSFET), which improves chip area utilization, provides flexibility in fine-tuning the trench width, and saves chip space.

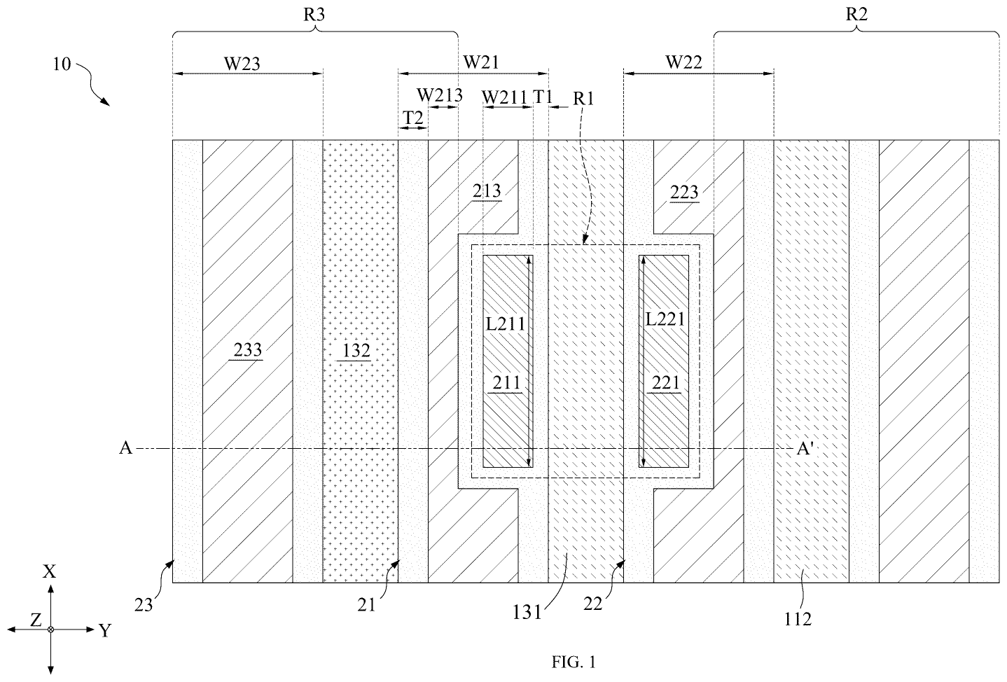

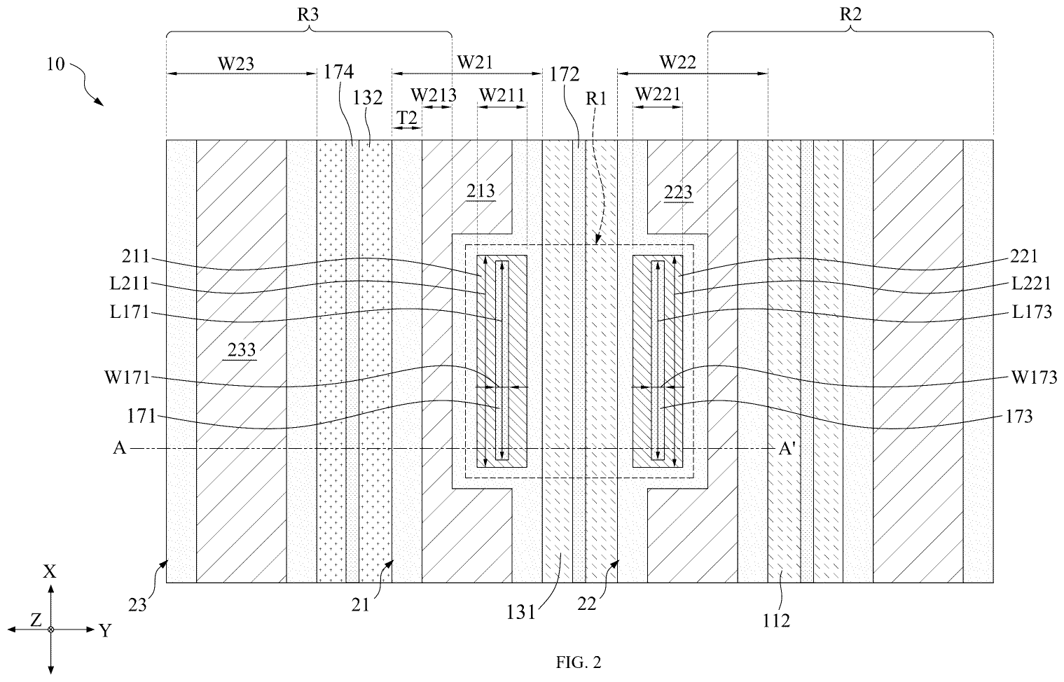

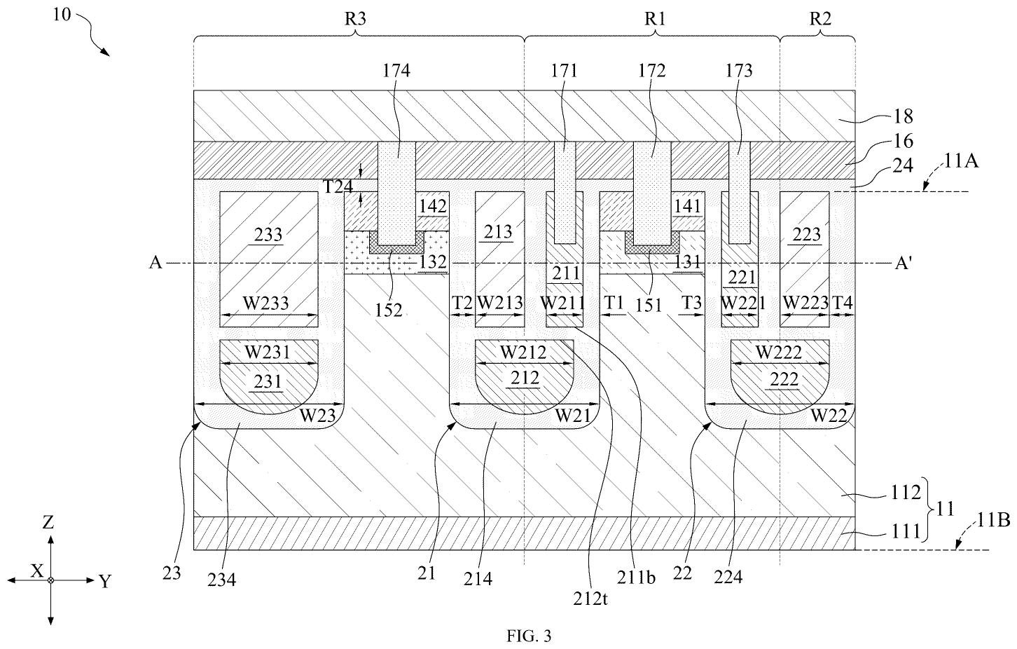

FIG. 1 and FIG. 2 are top views of a trench semiconductor structure 10 according to embodiments of the present disclosure. FIG. 2 shows conductive plugs provided in the trench semiconductor structure 10 as shown in FIG. 1. FIG. 3 is a cross-sectional view of the trench semiconductor structure 10 along a line AA′ according to embodiments of the present disclosure. Specifically, the trench semiconductor structure 10 is a trench MOS rectifier device structure having a vertical current conduction path. For example, the current of the trench semiconductor structure 10 may be conducted vertically through the trench semiconductor structure 10.

In some embodiments, referring to FIG. 1, FIG. 2 and FIG. 3, the trench semiconductor structure 10 includes a semiconductor material layer 11, a first trench structure 21, and a second trench structure 22. In some embodiments, the trench semiconductor structure 10 further includes a third trench structure 23, a first doped region 131, a second doped region 141, an interlayer dielectric layer 16, and a metal layer 18.

In some embodiments, the semiconductor material layer 11 includes a substrate 111 and an epitaxial layer 112 located on the substrate 111. In some embodiments, the substrate 111 includes, for example, silicon, silicon carbide (SiC), germanium (Ge), silicon germanium (SiGe), gallium nitride (GaN), gallium arsenide (GaAs), gallium arsenide phosphide (GaAsP), or other semiconductor materials. In some embodiments, the epitaxial layer 112 includes, for example, silicon, silicon carbide (SiC), germanium (Ge), silicon germanium (SiGe), gallium nitride (GaN), gallium arsenide (GaAs), gallium arsenide phosphide (GaAsP), or other semiconductor materials. The substrate 111 may be an N-type or P-type semiconductor material. The epitaxial layer 112 may be an N-type or P-type semiconductor material. In some embodiments, the substrate 111 and the epitaxial layer 112 have the same conductivity type, for example, the substrate 111 and the epitaxial layer 112 are both N-type.

The substrate 111 has doping of the same conductivity type as the epitaxial layer 112. In some embodiments, the substrate 111 is part of a silicon substrate or a silicon wafer. In some embodiments, the doping concentration of the substrate 111 is greater than the doping concentration of the epitaxial layer 112.

In some embodiments, the semiconductor material layer 11 is defined with a first region R1 and a second region R2 adjacent to the first region R1, viewed from a top view. The first region R1 includes an SBR, and the second region R2 includes an SGT MOSFET. In some embodiments, the semiconductor material layer 11 is further defined with a third region R3 adjacent to the first region RI viewed from a top view. In some embodiments, the first region R1 is located between the second region R2 and the third region R3 or is surrounded by the second region R2 and the third region R3, and the third region R3 also includes an SGT MOSFET.

The semiconductor material layer 11 may have a first surface 11A and a second surface 11B opposite to the first surface 11A. The second surface 11B and the first surface 11A may be located on opposite sides of the semiconductor material layer 11. The first surface 11A and the second surface 11B may be horizontal planes. For convenience of description, the direction perpendicular to the first surface 11A and the second surface 11B is defined as a vertical direction Z, and the plane formed by a first direction X and a second direction Y is perpendicular to the vertical direction Z. The plane formed by the first direction X and the second direction Y is parallel to the first surface 11A and the second surface 11B. The first direction X is perpendicular to the second direction Y, as shown in FIG. 1 and FIG. 2, and other figures. In some embodiments, the first surface 11A may be the active surface of the epitaxial layer 112. The bottom surface of the substrate 111 is the second surface 11B.

The first trench structure 21 extends from the first surface 11A towards the second surface 11B. The first trench structure 21 includes a first electrode 211, a first gate 213 adjacent to the first electrode 211, a second electrode 212 located below the first electrode 211 and the first gate 213, and a first oxide layer 214 separating the first electrode 211, the second electrode 212, and the first gate 213 from each other. The first electrode 211 is located between the first gate 213 and the first doped region 131. In some embodiments, the first electrode 211, the second electrode 212, and the first gate 213 are columnar structures. In some embodiments, the top surface of the first trench structure 21 is coplanar with the first surface 11A. In some embodiments, the top surface of the first electrode 211 and the top surface of the first gate 213 are coplanar with the first surface 11A. In some embodiments, the bottom surface of the first electrode 211 and the bottom surface of the first gate 213 may be at the same depth from the first surface 11A. From a top view, e.g., the top view as shown in FIG. 1 or FIG. 2, the first trench structure 21 extends in the first direction X parallel to the first surface 11A, and the first electrode 211 and the first gate 213 overlap with the second electrode 212 below.

The first oxide layer 214 is used to electrically isolate the epitaxial layer 112 from the first electrode 211, the second electrode 212 and the first gate 213. In other words, the first electrode 211, the second electrode 212 and the first gate 213 are separated from the epitaxial layer 112 through the first oxide layer 214 in the trench of the first trench structure 21. The first electrode 211, the second electrode 212 and the first gate 213 are respectively surrounded by the first oxide layer 214. At least a portion of the first oxide layer 214 is located between the first electrode 211 and the first gate 213. At least a portion of the first oxide layer 214 serves as the gate oxide layer of the SGT MOSFET located in the third region R3. In some embodiments, the first oxide layer 214 between the first electrode 211 and the semiconductor material layer 11 has a first thickness T1, and the first oxide layer 214 between the first gate electrode 213 and the semiconductor material layer 11 has a second thickness T2. The second thickness T2 is greater than the first thickness T1. In some embodiments, the first thickness T1 and the second thickness T2 are substantially the same. The first thickness T1 and the second thickness T2 may be adjusted according to the sizes or operating voltages of the first electrode 211 and the first gate 213, respectively.

In some embodiments, the first electrode 211 has a first width W211, the first gate 213 has a second width W213, and the second width W213 is greater than the first width W211. In some embodiments, the first width W211 and the second width W213 are substantially the same. The first width W211 is smaller than the width W212 of the second electrode 212, and the second width W213 is smaller than the width W212 of the second electrode 212. In some embodiments, the sum of the first width W211 and the second width W213 is smaller than the width W212 of the second electrode 212.

The semiconductor material layer 11 includes the first doped region 131. The first doped region 131 extends in the first direction X in the top views. In some embodiments, the first doped region 131 is disposed between the first surface 11A and the second surface 11B, adjacent to the first oxide layer 214 and separated from the first electrode 211. The first doped region 131 is located in the semiconductor material layer 11 adjacent to the first surface 11A and adjacent to the first trench structure 21. In some embodiments, the first doped region 131 is located in the epitaxial layer 112 and in contact with the first oxide layer 214. At least a portion of the first oxide layer 214 is located between the first electrode 211 and the first doped region 131.

The first doped region 131 is disposed between the first trench structure 21 and the second trench structure 22, and serves as a doped body region of the trench semiconductor structure 10. At least a portion of the epitaxial layer 112 is disposed between the first doped region 131 and the substrate 111. In some embodiments, the first doped region 131 has a conductivity type different from that of the epitaxial layer 112, for example, a conductivity type of a second type (a second conductivity type), which may be the N-type or the P-type. In some embodiments, the first doped region 131 is the P-type, and the epitaxial layer 112 is the N-type. The first doped region 131 includes a P-type dopant, and the P-type dopant may be, for example, boron, aluminum, gallium, indium, etc. In some embodiments, the P-type dopant included in the first doped region 131 is boron. The doping concentration of the first doped region 131 is greater than the doping concentration of the epitaxial layer 112. The depth of the first doped region 131 is less than the depth of the bottom surface 211b of the first electrode 211. The depth of the first doped region 131 is less than the depth of the top surface 212t of the second electrode 212.

The semiconductor material layer 11 further includes the second doped region 141. The second doped region 141 extends in the first direction X in the top views. In some embodiments, the second doped region 141 is located between the first surface 11A and the first doped region 131, adjacent to the first oxide layer 214, and separated from the first electrode 211. The second doped region 141 is located in the semiconductor material layer 11 adjacent to the first surface 11A and adjacent to the first trench structure 21. In some embodiments, the second doped region 141 is located in the epitaxial layer 112 and in contact with the first oxide layer 214. At least a portion of the first oxide layer 214 is located between the first electrode 211 and the second doped region 141.

The second doped region 141 is disposed between the first trench structure 21 and the second trench structure 22 and serves as the source of the trench semiconductor structure 10. In some embodiments, the second doped region 141 has the same conductivity type as the epitaxial layer 112, such as a conductivity type having a first type (first conductivity type), which may be the N-type or the P-type. The first type is different from the second type. In some embodiments, the second doped region 141 and the epitaxial layer 112 have the N-type. The doping concentration of the second doped region 141 may be greater than the doping concentration of the epitaxial layer 112. The depth of the second doped region 141 may be smaller than the depth of the bottom surface 211b of the first electrode 211. The depth of the second doped region 141 may be smaller than the depth of the top surface 212t of the second electrode 212.

The second trench structure 22 is spaced apart from the first trench structure 21. The first doped region 131 and the second doped region 141 are located between the first trench structure 21 and the second trench structure 22. The trench depth of the first trench structure 21 and the trench depth of the second trench structure 22 may be the same or different, and the trench width W21 of the first trench structure 21 and the trench width W22 of the second trench structure 22 may be the same or different. In some embodiments, the trench depth of the first trench structure 21 is the same as the trench depth of the second trench structure 22. The trench width W21 of the first trench structure 21 is the same as the trench width W22 of the second trench structure 22.

The second trench structure 22 extends from the first surface 11A towards the second surface 11B. The second trench structure 22 includes a third electrode 221, a second gate 223 adjacent to the third electrode 221, a fourth electrode 222 located below the third electrode 221 and the second gate 223, and a second oxide layer 224 separating the third electrode 221, the fourth electrode 222, and the second gate 223 from each other. The third electrode 221 is located between the second gate 223 and the first doped region 131. The first doped region 131 is located between the first electrode 211 and the third electrode 221. In some embodiments, the third electrode 221, the fourth electrode 222, and the second gate 223 are columnar structures, respectively. In some embodiments, the top surface of the second trench structure 22 is coplanar with the first surface 11A. In some embodiments, the top surface of the third electrode 221 and the top surface of the second gate 223 are coplanar with the first surface 11A. In some embodiments, the bottom surface of the third electrode 221 and the bottom surface of the second gate 223 may be at the same depth from the first surface 11A. From a top view, e.g., the top view as shown in FIG. 1 or FIG. 2, the second trench structure 22 extends in the first direction X parallel to the first surface 11A, and the third electrode 221 and the second gate 223 overlap with the fourth electrode 222 below.

The second oxide layer 224 is used to electrically isolate the third electrode 221, the fourth electrode 222, and the second gate 223 from the epitaxial layer 112. In other words, the third electrode 221, the fourth electrode 222, and the second gate 223 are separated from the epitaxial layer 112 by the second oxide layer 224 in the trench of the second trench structure 22. The third electrode 221, the fourth electrode 222, and the second gate 223 are respectively surrounded by the second oxide layer 224. At least a portion of the second oxide layer 224 is located between the third electrode 221 and the second gate 223. At least a portion of the second oxide layer 224 serves as a gate oxide layer of the SGT MOSFET located in the second region R2. In some embodiments, the second oxide layer 224 located between the third electrode 221 and the semiconductor material layer 11 has a third thickness T3, the second oxide layer 224 located between the second gate 223 and the semiconductor material layer 11 has a fourth thickness T4, and the fourth thickness T4 is greater than the third thickness T3. In some embodiments, the third thickness T3 and the fourth thickness T4 are substantially the same. The third thickness T3 and the fourth thickness T4 may be adjusted according to the sizes or operating voltages of the third electrode 221 and the second gate 223, respectively.

In some embodiments, the third electrode 221 has a third width W221, the second gate 223 has a fourth width W223, and the fourth width W223 is greater than the third width W221. In some embodiments, the third width W221 and the fourth width W223 are substantially the same. The third width W221 may be less than the width W222 of the fourth electrode 222. The fourth width W223 may be less than the width W222 of the fourth electrode 222. In some embodiments, the sum of the third width W221 and the fourth width W223 is less than the width W222 of the fourth electrode 222.

As shown in FIG. 3, the second doped region 141 is located between the first surface 11A and the first doped region 131 in the vertical direction Z, and between the first trench structure 21 and the second trench structure 22 in the second direction Y. The first doped region 131 is located between the second doped region 141 and the substrate 111 in the vertical direction Z. The second doped region 141 may be located on the first doped region 131. The top surface of the second doped region 141 may be coplanar with the first surface 11A, and the bottom surface of the second doped region 141 may be coplanar with (or in touch with) the top surface of the first doped region 131. Side surfaces of first doped region 131 and the second doped region 141 in the vertical direction Z may be in touch with the first oxide layer 214 and the second oxide layer 224, respectively. The first doped region 131 and the second doped region 141 may have the same width in the second direction Y. The sum of the depths of the first doped region 131 and the second doped region 141 extended into the epitaxial layer 112 from the first surface 11A may be less than the depth of the first electrode 211 and/or the depth of the second electrode 221. In some embodiments, the bottom surfaces of the first electrode 211 and the first gate 213 may be at the same depth as the bottom surfaces of the third electrode 221 and the second gate 223.

The trench semiconductor structure 10 includes an SBR. In some embodiments, the SBR is located in the first region R1, including the first electrode 211, the third electrode 221, the first doped region 131, and the second doped region 141. The first electrode 211, the third electrode 221, and the first doped region 131 and the second doped region 141 located between the first electrode 211 and the third electrode 221 are located in the first region R1. The first electrode 211 and the third electrode 221 are disposed between the first gate 213 and the second gate 223. From a top view, e.g., the top view shown in FIG. 1 or FIG. 2, the length L211 of the first electrode 211 along the first direction X and the length L221 of the third electrode 221 along the first direction X may be the same or different. In some embodiments, the SBR is surrounded by the second region R2, which includes an SGT MOSFET, and surrounded by the third region R3. The first gate 213 and the second gate 223 are located in the third region R3 and the the second region R2, respectively.

The semiconductor material layer 11 between the first trench structure 21 and the second trench structure 22 forms a mesa surface. In some embodiments, the mesa surface separates the first trench structure 21 from the second trench structure 22. The width of the mesa surface may be controlled by the positions of the first trench structure 21 and the second trench structure 22.

The third trench structure 23 is spaced apart from the first trench structure 21. The trench depth of the first trench structure 21 and the trench depth of the third trench structure 23 may be the same or different, and the trench width W21 of the first trench structure 21 and the trench width W23 of the third trench structure 23 may be the same or different. In some embodiments, the trench depth of the first trench structure 21 is the same as the trench depth of the third trench structure 23, and the trench width W21 of the first trench structure 21 is the same as the trench width W23 of the third trench structure 23.

The third trench structure 23 extends from the first surface 11 towards the second surface 11B and is disposed adjacent to the first trench structure 21. The third trench structure 23 includes a fifth electrode 231, a third gate 233 located over the fifth electrode 231, and a third oxide layer 234 separating the fifth electrode 231 and the third gate 233 from each other. In some embodiments, the fifth electrode 231 and the third gate 233 are columnar structures, respectively. In some embodiments, the top surface of the third trench structure 23 is coplanar with the first surface 11A. In some embodiments, the top surface of the third gate 233 is coplanar with the first surface 11A. In some embodiments, the bottom surface of the third gate 233 may be at the same depth as the bottom surfaces of the first electrode 211 and the first gate 213. From a top view, e.g., the top view as shown in FIG. 1 or FIG. 2, the third trench structure 23 extends in the first direction X parallel to the first surface 11A, and the third gate 233 overlaps with the fifth electrode 231 below.

The third oxide layer 234 is used to electrically isolate the fifth electrode 231 and the third gate 233 from the epitaxial layer 112. In other words, the fifth electrode 231 and the third gate 233 are separated from the epitaxial layer 112 by the third oxide layer 234 in the trench of the third trench structure 23. The fifth electrode 231 and the third gate 233 are respectively surrounded by the third oxide layer 234. At least a portion of the third oxide layer 234 is located between the fifth electrode 231 and the third gate 233. At least a portion of the third oxide layer 234 serves as a gate oxide layer of the SGT MOSFET located in the third region R3.

In some embodiments, the fifth electrode 231 has a fifth width W231, the third gate 233 has a sixth width W233, and the fifth width W231 is substantially the same as the sixth width W233. In some embodiments, the fifth width W231 is smaller than the sixth width W233.

A third doped region 132 may be disposed between the first trench structure 21 and the third trench structure 23, and extend in the first direction X in the top views. In some embodiments, the third doped region 132 is disposed between the first surface 11A and the second surface 11B, adjacent to the first oxide layer 214, and separated from the first gate 213. At least a portion of the first oxide layer 214 is located between the first gate 213 and the third doped region 132. In some embodiments, the third doped region 132 is located in the epitaxial layer 112 and is in contact with the first oxide layer 214 and the third oxide layer 234. The third doped region 132 is located in the semiconductor material layer 11 and adjacent to the first surface 11A. The third doped region 132 has the second conductivity type, and the first trench structure 21 is located between the first doped region 131 and the third doped region 132.

The third doped region 132 is disposed between the first trench structure 21 and the third trench structure 23, and serves as a doped body region of the trench semiconductor structure 10. At least a portion of the epitaxial layer 112 is disposed between the third doped region 132 and the substrate 111. In some embodiments, the third doped region 132 has a conductivity type different from that of the epitaxial layer 112, for example, a conductivity type of the second type. In some embodiments, the third doped region 132 has the P-type, and the epitaxial layer 112 has the N-type. The third doped region 132 includes a P-type dopant, and the P-type dopant may be, for example, boron, aluminum, gallium, indium, etc. In some embodiments, the P-type dopant included in the third doped region 132 is boron. The doping concentration of the third doped region 132 may be greater than the doping concentration of the epitaxial layer 112. In some embodiments, the doping concentration of the third doped region 132 may be different from the doping concentration of the first doped region 131. In some embodiments, the doping concentration of the third doped region 132 is greater than the doping concentration of the first doped region 131. The depth of the third doped region 132 may be less than the depth of the bottom surface 211b of the first electrode 211. The depth of the third doped region 132 may be less than the depth of the top surface 212t of the second electrode 212. The depth of the third doped region 132 may be the same as or different from the depth of the first doped region 131.

The semiconductor material layer 11 further includes a fourth doped region 142. The fourth doped region 142 extends in the first direction X in the top views. In some embodiments, the fourth doped region 142 is located between the first surface 11A and the third doped region 132, adjacent to the first oxide layer 214 and separated from the first gate 213. The fourth doped region 142 is located in the semiconductor material layer 11 adjacent to the first surface 11A and adjacent to the first trench structure 21. In some embodiments, the fourth doped region 142 is located in the epitaxial layer 112 and in contact with the first oxide layer 214. At least a portion of the first oxide layer 214 is located between the first gate 213 and the fourth doped region 142.

The fourth doped region 142 is disposed between the first trench structure 21 and the third trench structure 23, and serves as the source of the trench semiconductor structure 10. In some embodiments, the fourth doped region 142 has the same conductivity type as the epitaxial layer 112, for example, the first conductivity type. In some embodiments, the fourth doped region 142 and the epitaxial layer 112 have the N-type. The doping concentration of the fourth doped region 142 is greater than the doping concentration of the epitaxial layer 112. The depth of the fourth doped region 142 is less than the depth of the bottom surface of the first gate 213. The depth of the fourth doped region 142 is less than the depth of the top surface 212t of the second electrode 212. The doping concentration of the second doped region 141 may be the same as or different from the doping concentration of the fourth doped region 142.

As shown in FIG. 3, the fourth doped region 142 is located between the first surface 11A and the third doped region 132 in the vertical direction Z, and between the first trench structure 21 and the third trench structure 23 in the second direction Y. The third doped region 132 is located between the fourth doped region 142 and the substrate 111 in the vertical direction Z. The fourth doped region 142 may be located on the third doped region 132. The top surface of the fourth doped region 142 may be coplanar with the first surface 11A, and the bottom surface of the fourth doped region 142 may be coplanar with (or in touch with) the top surface of the third doped region 132. Side surfaces of third doped region 132 and the fourth doped region 142 in the vertical direction Z may be in touch with the first oxide layer 214 and the third oxide layer 234, respectively. The third doped region 132 and the fourth doped region 142 may have the same width in the second direction Y. The sum of the depths of the third doped region 132 and the fourth doped region 142 extended into the epitaxial layer 112 from the first surface 11A may be less than the depth of the first gate 213, the depth of the first electrode 211 and/or the depth of the third gate 233. In some embodiments, the bottom surfaces of the first electrode 211 and the first gate 213 may be at the same depth as the bottom surfaces of the third electrode 221 and the second gate 223.

The interlayer dielectric layer 16 is located on the first surface 11A of the semiconductor material layer 11, and is used to separate the metal layer 18 located on the interlayer dielectric layer 16 from the semiconductor material layer 11, the first trench structure 21, the second trench structure 22, and the third trench structure 23. The interlayer dielectric layer 16 covers the first trench structure 21, the second trench structure 22, the third trench structure 23, the second doped region 141, and the fourth doped region 142. In some embodiments, the metal layer 18 may be the source of the trench semiconductor structure 10. In some embodiments, the metal layer 18 may be a patterned metal wire layer for adjusting electrical paths according to actual operation requirements, e.g., the metal layer 18 may include multiple metal wires electrically connected to different electrodes or doped regions. In some embodiments, the metal layer 18 may be the first metal layer (M1) in a interconnect structure. The metal layer 18 includes a conductive material, such as a metal, which may be, for example but not limited to, copper (Cu), gold (Au), silver (Ag), aluminum (Al), nickel (Ni), titanium (Ti), tungsten (W), tin (Sn), titanium nitride (TiN), aluminum silicon (AlSi) alloy, aluminum silicon copper (AlSiCu) alloy or other metals or alloys.

In some embodiments, a fourth oxide layer 24 is located between the first surface 11A of the semiconductor material layer 11 and the interlayer dielectric layer 16. The fourth oxide layer 24 is located between the interlayer dielectric layer 16 and the first trench structure 21, the second trench structure 22, the third trench structure 23, the second doped region 141, and the fourth doped region 142. In some embodiments, the fourth oxide layer 24 and the first oxide layer 214, the second oxide layer 224, and the third oxide layer 234 include the same or different materials. The thickness T24 of the fourth oxide layer 24 may be less than the second thickness T2 of the first oxide layer 214 located between the first gate 213 and the semiconductor material layer 11.

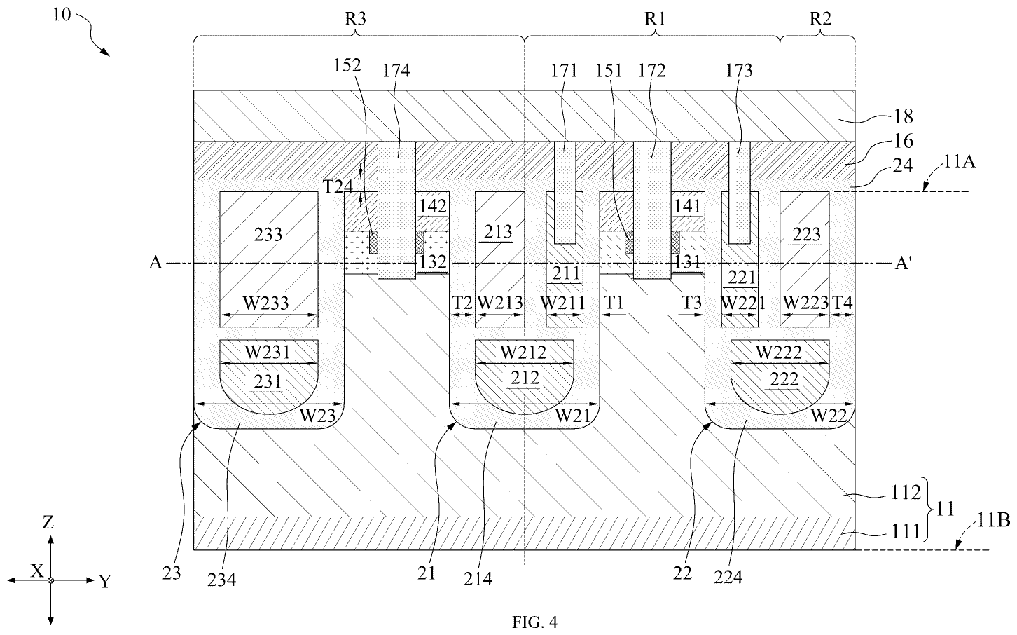

The first electrode 211 and the first doped region 131 may be electrically connected to the metal layer 18, respectively. In some embodiments, a first conductive plug 171 may be provided extending through the interlayer dielectric layer 16 to electrically connect the first electrode 211 to the metal layer 18. A second conductive plug 172 may be provided extending through the interlayer dielectric layer 16 and the second doped region 141, and at least a portion of the second conductive plug 172 is surrounded by the first doped region 131 and electrically connected to the metal layer 18. In some embodiments, the second conductive plug 172 may extend through the first doped region 131 as shown in FIG. 4.

The third electrode 221 and the third doped region 132 may also be electrically connected to the metal layer 18. In some embodiments, a third conductive plug 173 may be provided extending through the interlayer dielectric layer 16 to electrically connect the third electrode 221 to the metal layer 18. A fourth conductive plug 174 may be provided extending through the interlayer dielectric layer 16 and the fourth doped region 142, and at least a portion of the fourth conductive plug 174 is surrounded by the third doped region 132 and electrically connected to the metal layer 18. In some embodiments, the fourth conductive plug 174 passes through the third doped region 132 as shown in FIG. 4. The bottom of the fourth conductive plug 174 is located at the epitaxial layer 112.

The first conductive plug 171, the second conductive plug 172, the third conductive plug 173, and the fourth conductive plug 174 extend from above the first surface 11A of the semiconductor material layer 11 toward the second surface 11B along the vertical direction Z. The first conductive plug 171 may extend from above the first surface 11A, through the interlayer dielectric layer 16, and into the first electrode 211. The second conductive plug 172 may extend from above the first surface 11A, through the interlayer dielectric layer 16 and the second doped region 141, and into the first doped region 131 or through the first doped region 131 into the epitaxial layer 112. The third conductive plug 173 may extend from above the first surface 11A, through the interlayer dielectric layer 16, and into the third electrode 221. The fourth conductive plug 174 may extend from above the first surface 11A, through the interlayer dielectric layer 16 and the fourth doped region 142, and into the third doped region 132 or through the third doped region 132 into the epitaxial layer 112. When the fourth oxide layer 24 is provided, these four conductive plugs extend through the fourth oxide layer 24. FIG. 2 shows the conductive plugs 171-174 in the top view. In some embodiments, the first conductive plug 171, the second conductive plug 172, and the third conductive plug 173 are located in the first region R1, and the fourth conductive plug 174 is located in the second region R2 or the third region R3.

In some embodiments, a doped region 151 may be provided in the first doped region 131 and serves as a heavily doped region in the first doped region 131 (hereinafter the doped region 151 is generally referred to as a heavily doped region 151). The heavily doped region 151 has the same conductivity type as the first doped region 131, such as the P-type. In some embodiments, the doping concentration of the heavily doped region 151 is greater than the doping concentration of the first doped body region 131. In some embodiments, the heavily doped region 151 is located in the first doped region 131 and is separated from the first oxide layer 214 and the second oxide layer 224. In some embodiments, the heavily doped region 151 is disposed between the adjacent first doped region 131 and the second doped region 141. The heavily doped region 151 is located below the second conductive plug 172. A portion of the heavily doped region 151 may be located between the second conductive plug 172 and the first trench structure 21, and another portion of the heavily doped region 151 may be located between the second conductive plug 172 and the second trench structure 22. In other words, the heavily doped region 151 surrounds the bottom of the second conductive plug 172 disposed in the first doped region 131 to reduce the ohmic contact resistance.

In some embodiments, the heavily doped region 151 is located in the first doped region 131 and below the second doped region 141. A top surface of the heavily doped region 151 may be in touch with the bottom surface of the second doped region 141. A depth of the heavily doped region 151 is smaller than that of the first doped region 131 in the vertical direction Z. A width of the heavily doped region 151 is smaller than that of the first doped region 131 in the second direction Y. The heavily doped region 151 may be located in the middle of the first doped region 131 in the second direction Y. The second conductive plug 172 extends into the first doped region 131, and may stop in the heavily doped region 151 as shown in FIG. 3, or extend through the heavily doped region 151 as shown in FIG. 4.

A doped region 152 may be provided in the third doped region 132 and serves as a heavily doped region in the third doped region 132 (hereinafter the doped region 152 is generally referred to as a heavily doped region 152). The heavily doped region 152 has the same conductivity type as the third doped region 132, for example, the P-type. In some embodiments, the doping concentration of the heavily doped region 152 is greater than the doping concentration of the third doped body region 132. In some embodiments, the heavily doped region 152 is located in the third doped region 132 and is separated from the first oxide layer 214 and the third oxide layer 234. In some embodiments, the heavily doped region 152 is disposed between the adjacent third doped region 132 and the fourth doped region 142. The heavily doped region 152 is located below the fourth conductive plug 174, a portion of the heavily doped region 152 is located between the fourth conductive plug 174 and the first trench structure 21, and another portion of the heavily doped region 152 is located between the fourth conductive plug 174 and the third trench structure 23. In other words, the heavily doped region 152 surrounds the bottom of the fourth conductive plug 174 disposed in the third doped region 132 to reduce the ohmic contact resistance.

In some embodiments, the heavily doped region 152 is located in the third doped region 132 and below the fourth doped region 142. A top surface of the heavily doped region 152 may be in touch with the bottom surface of the fourth doped region 142. A depth of the heavily doped region 152 is smaller than that of the third doped region 132 in the vertical direction Z. A width of the heavily doped region 152 is smaller than that of the third doped region 132 in the second direction Y. The heavily doped region 152 may be located in the middle of the third doped region 132 in the second direction Y. The fourth conductive plug 174 extends into the third doped region 132, and may stop in the heavily doped region 152 as shown in FIG. 3, or extend through the heavily doped region 152 as shown in FIG. 4.

In some embodiments, referring to FIG. 2, from the top view, the first conductive plug 171 is located on the first electrode 211 and extends in the first direction X. The length L171 of the first conductive plug 171 along the first direction X is less than the length L211 of the first electrode 211 along the first direction X. The width W171 of the first conductive plug 171 is less than the first width W211 of the first electrode 211. The second conductive plug 172 is located on the first doped region 131 and extends in the first direction X. The second conductive plug 172 and the first doped region 131 may have the same length in the first direction X.

The third conductive plug 173 is located on the third electrode 221 and extends in the first direction X. The length L173 of the third conductive plug 173 along the first direction X is less than the length L221 of the third electrode 221 along the first direction X. The width W173 of the third conductive plug 173 is less than the third width W221 of the third electrode 221. The fourth conductive plug 174 is located in the third doped region 132 and extends in the first direction X. In some embodiments, the first electrode 211, the third electrode 221, the first conductive plug 171, the third conductive plug 173 and the metal layer 18 are all connected to the source.

FIG. 4 is a cross-sectional view of the trench semiconductor structure 10 along the line A-A′ according to some embodiments of the present disclosure. FIG. 4 shows another embodiment configuration of the four conductive plugs 171-174. In some embodiments, referring to FIG. 4, the fourth conductive plug 174 extends through the third doped region 132 and the heavily doped region 152, and the heavily doped region 152 surrounds at least a portion of the fourth conductive plug 174. The bottom of the fourth conductive plug 174 is located in the epitaxial layer 112. In some embodiments, the second conductive plug 172 extends through the first doped region 131 and the heavily doped region 151, and the heavily doped region 151 surrounds at least a portion of the second conductive plug 172. The bottom of the second conductive plug 172 is located in the epitaxial layer 112.

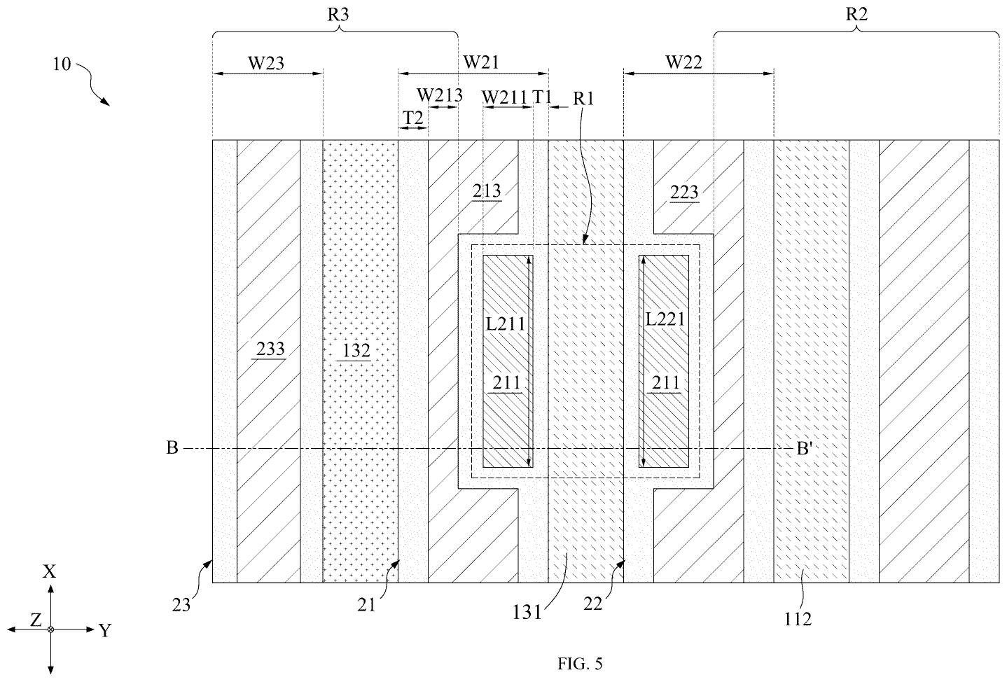

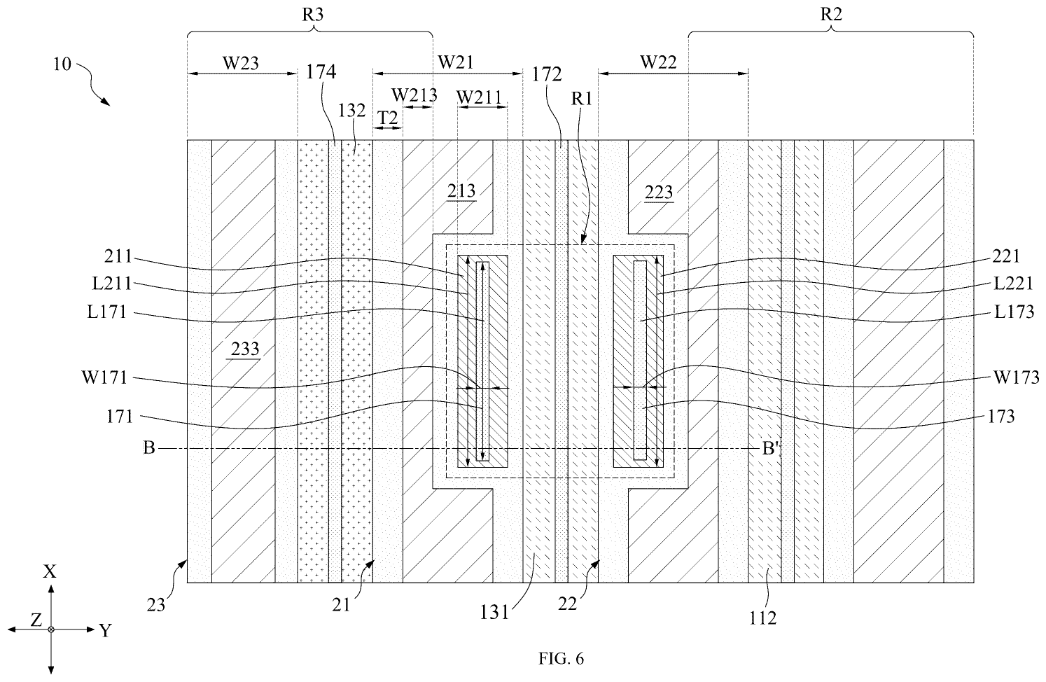

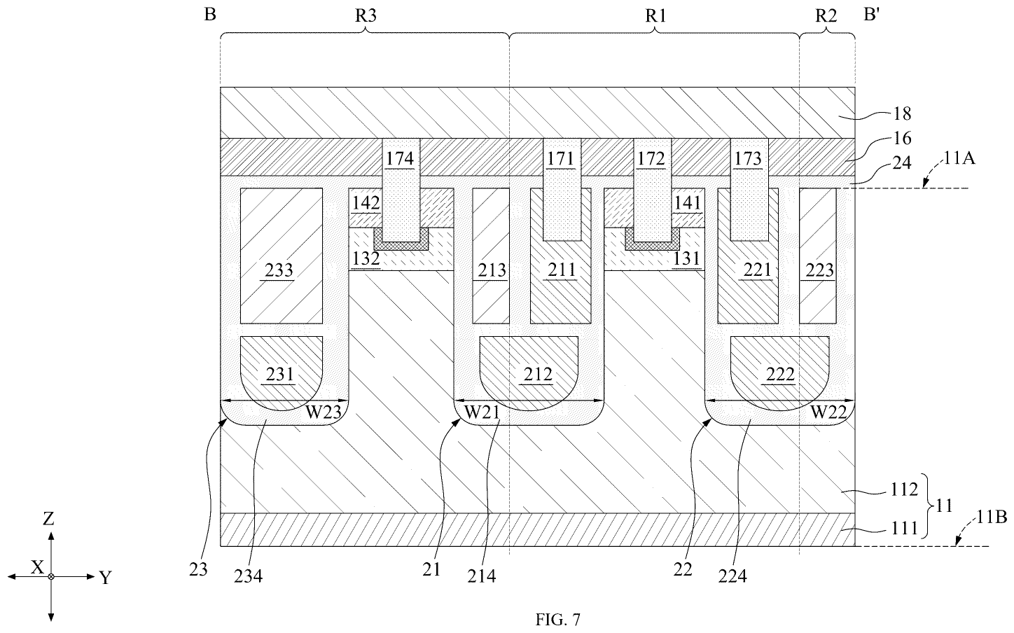

FIG. 5 and FIG. 6 are top views of another trench semiconductor structure 10 according to embodiments of the present disclosure. FIG. 7 is a cross-sectional view of the trench semiconductor structure 10 of FIG. 5 and FIG. 6 along a line BB′ according to some embodiments of the present disclosure. The trench semiconductor structure 10 of FIG. 5 and FIG. 6 may be similar to the trench semiconductor structure 10 of FIG. 1 and FIG. 2. FIG. 6 shows conductive plugs provided in the trench semiconductor structure 10 of FIG. 5. In the embodiments of FIG. 5, FIG. 6 and FIG. 7, the trench width W21 of the first trench structure 21 is different from the trench width W23 of the third trench structure 23. In some embodiments, the width W23 of the third trench structure 23 is smaller than the width W21 of the first trench structure 21.

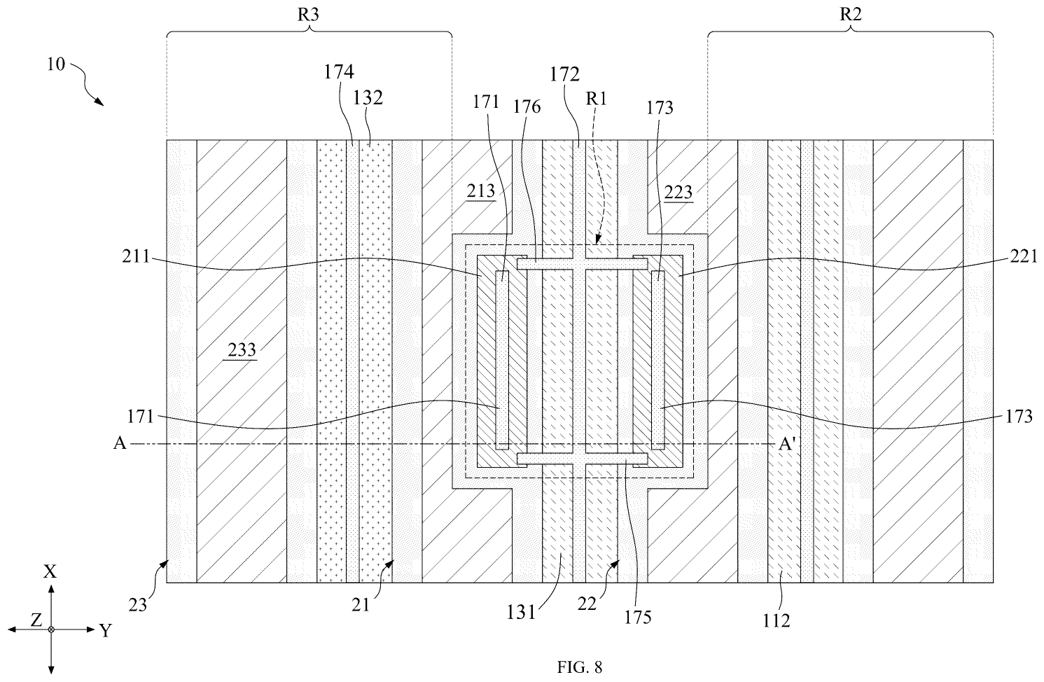

FIG. 8 is a top view of another trench semiconductor structure 10 according to embodiments of the present disclosure. The trench semiconductor structure 10 of FIG. 8 is similar to the trench semiconductor structure 10 of FIG. 8 of FIG. 2 and FIG. 3. In some embodiments, in the first region R1, the SBR may be surrounded by a plurality of conductive plugs. As described above, the SBR may include the first electrode 211, the third electrode 221, the first doped region 131, and the second doped region 141. In some embodiments, in the first region R1, from the top view, at least a portion of the first doped region 131 may be surrounded by a plurality of conductive plugs.

As an example, referring to FIG. 3 and FIG. 8, the trench semiconductor structure 10 may further include a fifth conductive plug 175 and/or a sixth conductive plug 176 located in the first region R1 and extending from above the first surface 11A of the semiconductor material layer 11 along the vertical direction Z towards the second surface 11B.

The fifth conductive plug 175 and the sixth conductive plug 176 are in contact with the second conductive plug 172, respectively. The fifth conductive plug 175 and the sixth conductive plug 176 are not in contact with the first conductive plug 171 and the third conductive plug 173. The fifth conductive plug 175 and the sixth conductive plug 176 do not extend in the first direction X. In some embodiments, the fifth conductive plug 175 and the sixth conductive plug 176 extend in the second direction Y and are orthogonal to (perpendicular to) the second conductive plug 172. The fifth conductive plug 175 is electrically connected to the metal layer 18, the first electrode 211, the third electrode 221, and the first doped region 131. The sixth conductive plug 176 is electrically connected to the metal layer 18, the first electrode 211, the third electrode 221, and the first doped region 131. The first conductive plug 171, the third conductive plug 173, the fourth conductive plug 174, the fifth conductive plug 175, and the sixth conductive plug 176 are separated from each other.

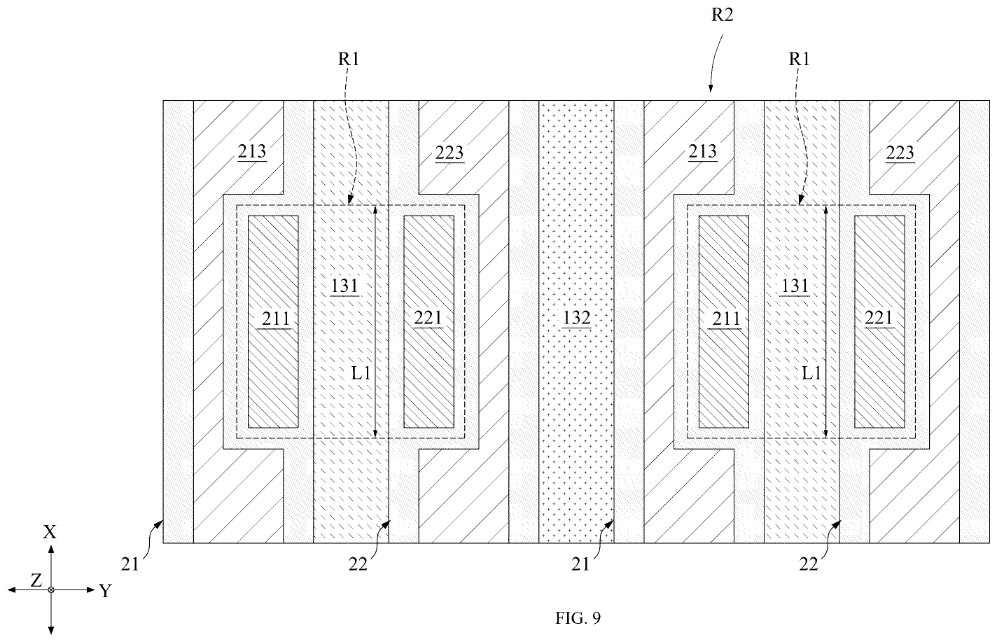

FIG. 9 to FIG. 12 are top views of trench semiconductor structures 10 according to embodiments of the present disclosure. FIG. 9 to FIG. 12 show various embodiment configurations and/arrangements that the first trench structure 21 and the second trench structure 22 may have in the trench semiconductor structures 10.

In some embodiments, referring to FIG. 9, the trench semiconductor structure 10 includes a plurality of first trench structures 21 and a plurality of second trench structures 22. Each of the first trench structures 21 is similar to the first trench structure 21 as described with respect to FIGS. 1-3. Each of the second trench structures 22 is similar to the second trench structure 22 as described with respect to FIGS. 1-3. From the top view, the first trench structures 21 and the second trench structures 22 are arranged alternately, with each first trench structure 21 corresponding to a second trench structure 22. As an example, one first doped region 131 may be disposed between each first trench structure 21 and its corresponding second trench structure 22A. The configuration of the first doped region 131 is similar to that described above.

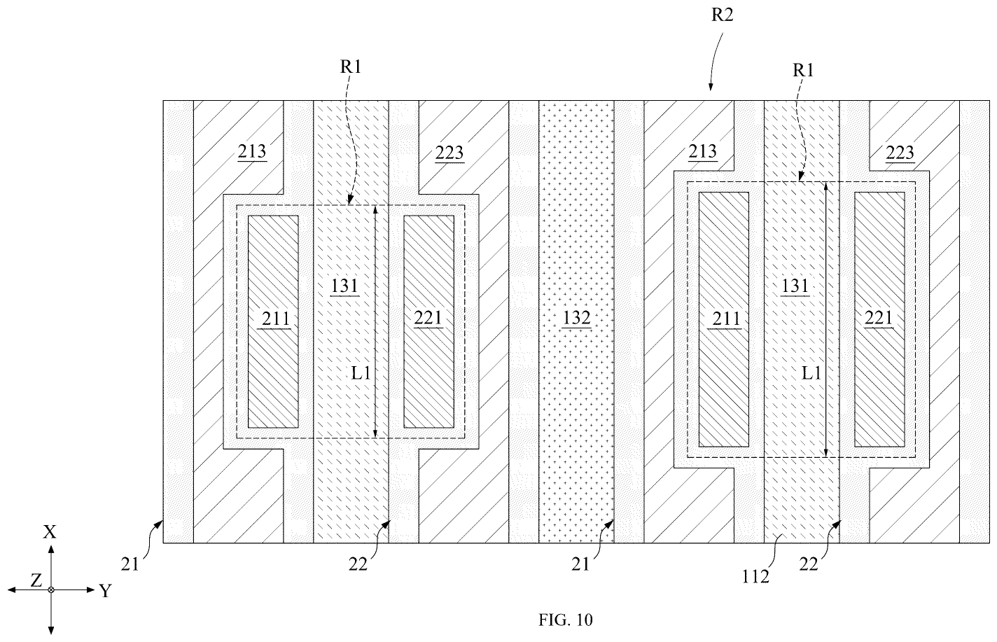

A first trench structure 21 and its corresponding second trench structure 22 may be referred to as a trench structure pair. One third doped region 132 is disposed between two adjacent trench structure pairs. Each first trench structure 21 and its corresponding second trench structure 22 form a first region R1, and each first region R1 includes an SBR. As an example, the first electrode 211 of each first trench structure 21 and the third electrode 221 of the corresponding second trench structure 22 form a first region R1. The SBR includes the first electrode 211, the third electrode 221, the first doped region 131 and possibly other components as described above. The size and/or configuration of each first region RI may be the same as or different from others. From the top view, the length LI of the plurality of first regions R1 along the first direction X may be the same. In some embodiments, referring to FIG. 10, from the top view, the lengths L1 of the plurality of first regions R1 along the first direction X may be different. In FIG. 9 and FIG. 10, a plurality of trench structure pairs are disposed along the second direction Y, and spaced apart by the third doped regions 132.

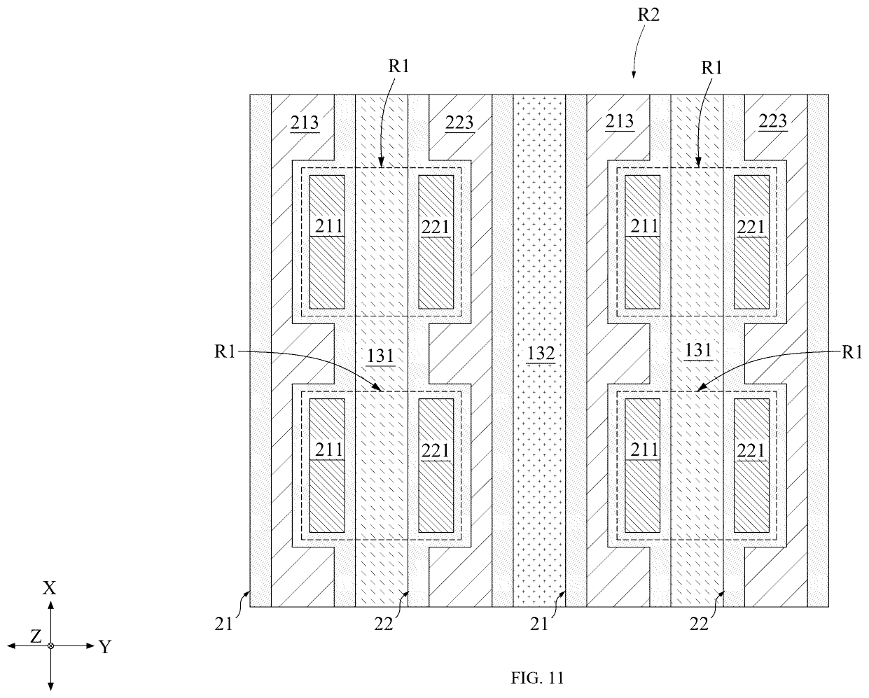

In some embodiments, referring to FIG. 11, from the top view, each first trench structure 21 and the corresponding second trench structure 22 form a plurality of first regions R1, and each first region R1 includes an SBR. In some embodiments, each first trench structure 21 includes a plurality of first electrodes 211, each second trench structure 22 includes a plurality of third electrodes 221, and each first electrode 211 corresponds to a third electrode 221. Each first electrode 211 and its corresponding third electrode 221 form a first region R1. The plurality of first electrodes 211 and the plurality of third electrodes 221 are located between the first gate 213 and the second gate 223. At least a portion of the first gate 213 is located between adjacent first electrodes 211, and at least a portion of the second gate 223 is located between adjacent third electrodes 221.

In other words, in the example of FIG. 11, two or more trench structure pairs may be disposed along the first direction X, which may be referred to as a trench structure group. Each trench structure pair may form a first region R1, similarly to that of FIG. 9. A plurality of such trench structure groups may be disposed along the second direction Y, where adjacent trench structure groups are spaced apart by one third doped region 132.

In some embodiments, referring to FIG. 9 to FIG. 11, the trench semiconductor structures 10 each includes a plurality of first regions R1 and a plurality of SBRs. Each first region R1 is provided with a first doped region 131, and a second region R2 including a third doped region 132 is provided between adjacent first regions R1. The second region R2 is disposed between the plurality of first regions R1. In some embodiments, the third doped region 132 is located between the first gate 213 and the second gate 223.

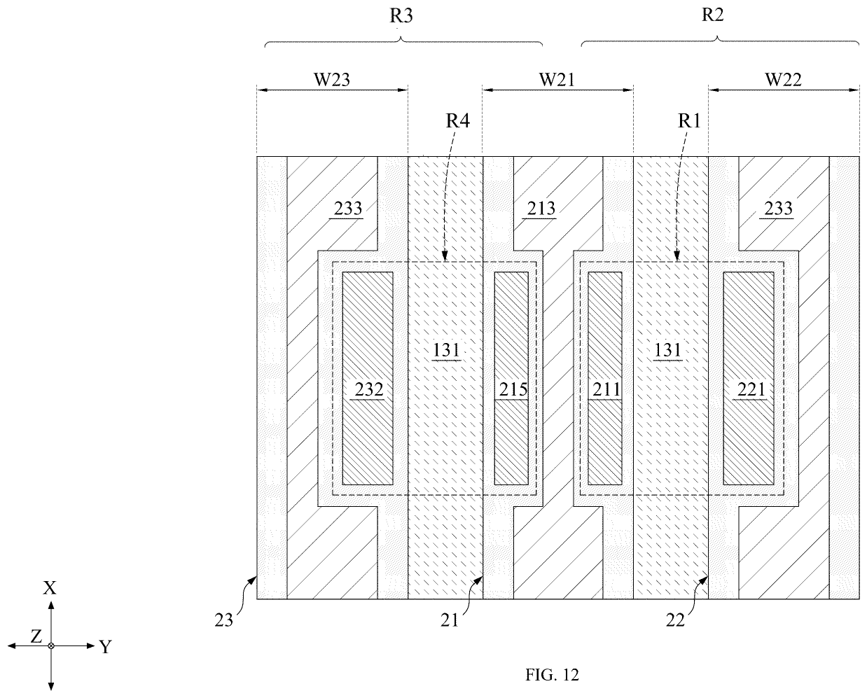

In some embodiments, referring to FIG. 12, the trench semiconductor structure 10 includes a first trench structure 21, a second trench structure 22, and a third trench structure 23. The second trench structure 22 is similar to the second trench structure 22 as described with respect to FIGS. 1-3. The first trench structure 21 is similar to the first trench structure 21 as described with respect to FIGS. 1-3, and may further include a sixth electrode 215. At least a portion of the first gate 213 is located between the first electrode 211 and the sixth electrode 215. The first oxide layer 214 surrounds the first electrode 211, the sixth electrode 215 and the first gate 213, and separates the first electrode 211, the sixth electrode 215 and the first gate 213 from each other. In some embodiments, the first gate 213 has different widths along the first direction X. From the top view, at least a portion of the first gate 213 is recessed from two sides toward the center, which, however, does not cause the first gate 213 to break apart. The first electrode 211 and the sixth electrode 215 are respectively located at two recesses of the first gate 213.

In other words, the first gate 213 is in a shape of a rectangle with the two recesses at two opposite sides (e.g., the longer sides) respectively. Each of the two recesses is recessed from a respective side toward a central axis of the first gate 213 parallel to the two opposite sides. In the example as shown in FIG. 12, the central axis of the first gate 213 is in parallel to the first direction X. The two recesses may be symmetric to each other about the central axis. There is at least a portion of the first gate 213 between the two recesses. A first doped region 131 similar to that described with respect to FIGS. 1-3 is disposed between the first trench structure 21 and the second trench structure 22.

In some embodiments, the third trench structure 23 is similar to the third trench structure 23 as described with respect to FIGS. 1-3, and may further include a seventh electrode 232 disposed above the fifth electrode 231. The fifth electrode 231 is located below the third gate 233 and the seventh electrode 232, and the third oxide layer 234 separates the fifth electrode 231, the third gate 233 and the seventh electrode 232 from each other. In some embodiments, the sixth electrode 215 is disposed opposite to the seventh electrode 232, and another first doped region 131 is disposed between the first trench structure 21 and the third trench structure 23.

In some embodiments, the semiconductor material layer 11 may have a fourth region R4 adjacent to the second region R2 or the third region R3 and different from the first region R1. The sixth electrode 215 and the seventh electrode 232 are located in the fourth region R4. The fourth region R4 includes a SBR. The first gate 213 is located between the first region R1 and the fourth region R4. In some embodiments, the first trench structure 21 is in the first region R1, the second region R2, and the fourth region R4 at the same time.

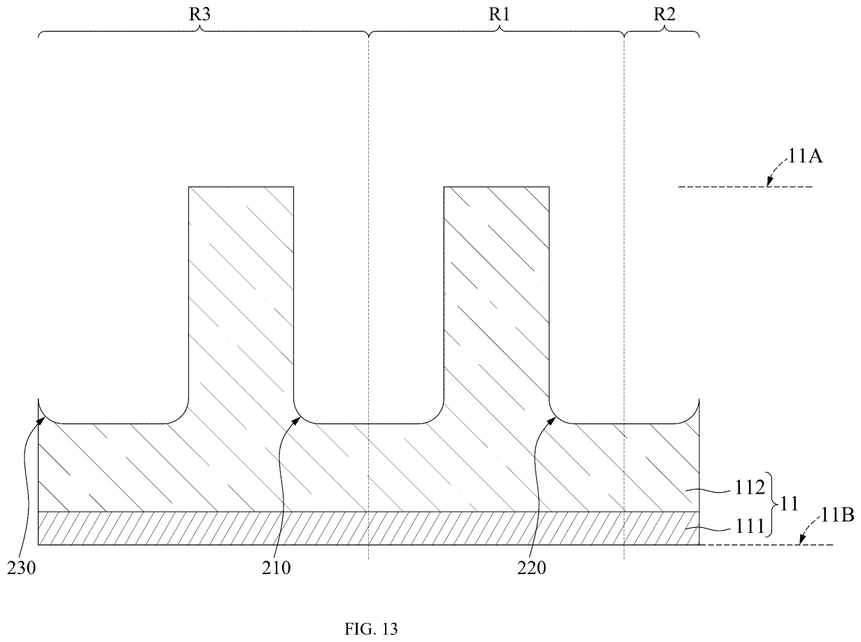

FIG. 13 to FIG. 35 illustrate one or more stages in a manufacturing method of a trench semiconductor structure according to embodiments of the present disclosure. FIG. 13 to FIG. 35 are top views of the trench semiconductor structure in various stages of manufacturing the trench semiconductor structure. At least some of these figures have been simplified to facilitate a better understanding of aspects of the present disclosure.

Referring to FIG. 13, the trench semiconductor structure includes a semiconductor material layer 11, and the semiconductor material layer 11 may include a substrate 111 and an epitaxial layer 112 located on the substrate 111. The manufacturing method includes performing epitaxial growth on the substrate 111 to form the epitaxial layer 112. The epitaxial layer 112 has a first surface 11A of the semiconductor material layer 11, the substrate 111 has a second surface 11B of the semiconductor material layer 11, and the first surface 11A is opposite to the second surface 11B. In some embodiments, ion implantation is performed simultaneously with the epitaxial growth, and ions with N-type electrical properties are implanted to form an N-type epitaxial layer 112.

The trench semiconductor structure includes a first trench 210, a second trench 220 and a third trench 230 as shown in FIG. 13. In some embodiments, a first patterned shielding layer (not shown) may be formed on the epitaxial layer 112 to define positions of the first trench 210, the second trench 220 and the third trench 230. The first trench 210, the second trench 220 and the third trench 230 may be formed at intervals by etching the epitaxial layer 112 (e.g., plasma dry etching) through the first patterned shielding layer. As an example, an etching process needle removes portions of the epitaxial layer 112 from the first surface 11A and stops in the epitaxial layer 112. According to the positions defined by the first patterned shielding layer, the first trench 210, the second trench 220 and the third trench 230 are formed at intervals in the semiconductor material layer 11 along the second direction Y, and extend from the first surface 11A towards the second surface 11B opposite to the first surface 11A. The trench semiconductor structure includes a first region R1, a second region R2 and a third region R3 as shown. Part of the first trench 210 and part of the second trench 220 are formed in the first region RI of the semiconductor material layer 11, part of the second trench 220 is formed in the second region R2 of the semiconductor material layer 11, and the third trench 230 is formed in the third region R3 of the semiconductor material layer 11. The first region R1 is located between the second region R2 and the third region R3.

In some embodiments, the first trench 210, the second trench 220 and the third trench 230 may have vertical sidewalls in the vertical direction Z. The first trench 210, the second trench 220 and the third trench 230 may have arc-shaped bottom surfaces. As an example, the first trench 210, the second trench 220 and the third trench 230 may each have opposite sidewalls and a bottom (or base) surface extending between the opposite sidewalls. The first trench 210, the second trench 220 and the third trench 230 each may be circular, elliptical, rectangular or polygonal. In some embodiments, the first trench 210, the second trench 220 and the third trench 230 have the same width. In some embodiments, the first trench 210, the second trench 220 and the third trench 230 have the same depth.

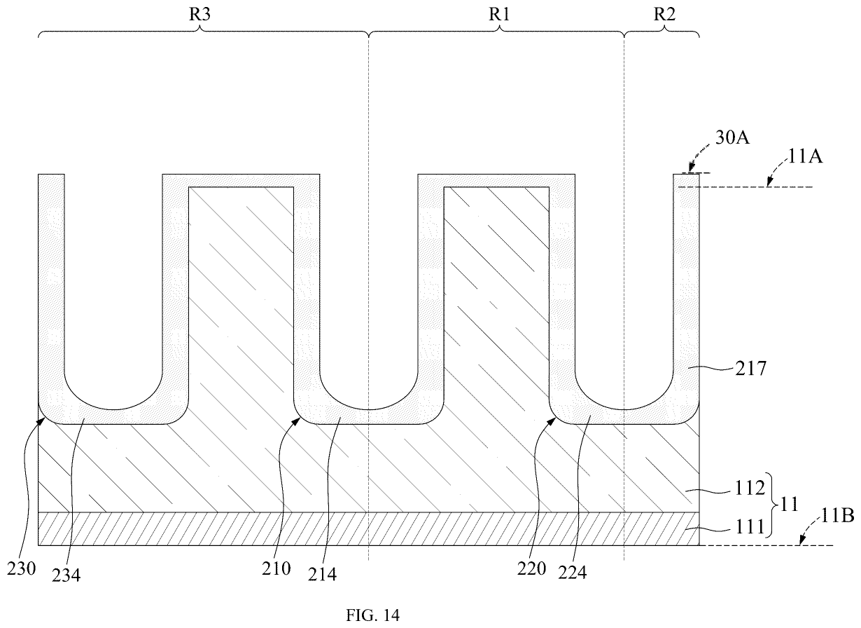

Referring to FIG. 14, the manufacturing method includes forming a first in-trench oxide layer 217 in the first trench 210, the second trench 220 and the third trench 230. In some embodiments, the first in-trench oxide layer 217 also covers the first surface 11A. In some embodiments, the first in-trench oxide layer 217 may be formed by thermal oxidation technology or other deposition processes, such as atomic layer deposition (ALD), chemical vapor deposition (CVD), or other deposition methods. In some embodiments, the first in-trench oxide layer 217 may be conformally deposited on the inner side surfaces (including the opposite sidewalls and the bottom extending between the opposite sidewalls) of each of the first trench 210, the second trench 220, and the third trench 230. In some embodiments, the first in-trench oxide layer 217 may be filled into the first trench 210, the second trench 220, and the third trench 230 through a deposition process, such that the first in-trench oxide layer 217 forms at least one groove in the first trench 210, the second trench 220, and the third trench 230, respectively. As an example, one groove is formed in each of the first trench 210, the second trench 220, and the third trench 230 after the first in-trench oxide layer 217 is filled in the first trench 210, the second trench 220, and the third trench 230. In some embodiments, a portion of the first in-trench oxide layer 217 in the first trench 210 is referred to as a first oxide layer 214, a portion of the first in-trench oxide layer 217 in the second trench 220 is referred to as a second oxide layer 224, and a portion of the first in-trench oxide layer 217 in the third trench 230 is referred to as a third oxide layer 234. The first oxide layer 214, the second oxide layer 224, and the third oxide layer 234 are formed simultaneously.

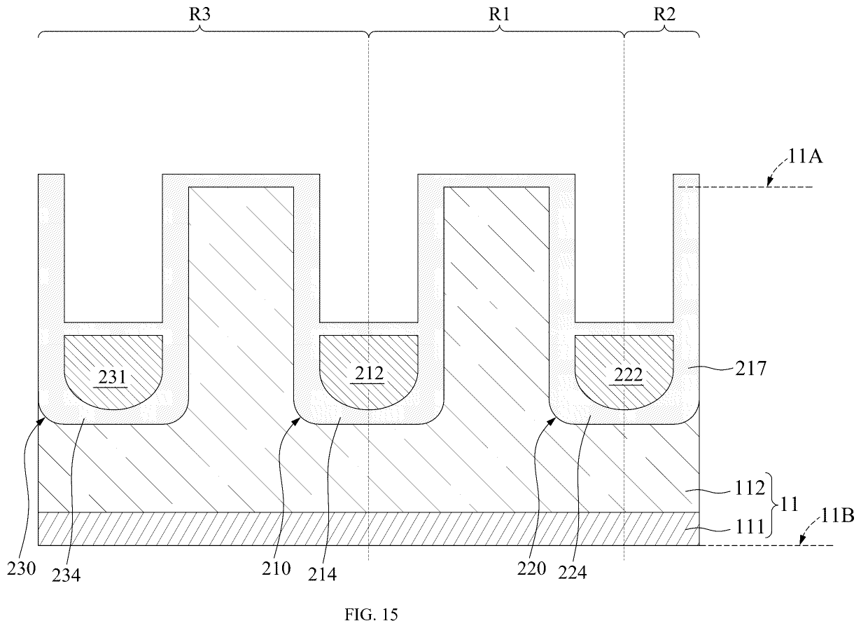

Referring to FIG. 15, the manufacturing method includes forming a second electrode 212, a fourth electrode 222, and a fifth electrode 231 in the first trench 210, the second trench 220, and the third trench 230, respectively. The second electrode 212, the fourth electrode 222, and the fifth electrode 231 are formed simultaneously. In some embodiments, the second electrode 212 is placed in the first trench 210 and on the top surface of the first oxide layer 214, the fourth electrode 222 is placed in the second trench 220 and on the top surface of the second oxide layer 224, and the fifth electrode 231 is placed in the third trench 230 and on the top surface of the third oxide layer 234, and then the first in-trench oxide layer 217 is formed on the top surfaces of the second electrode 212, the fourth electrode 222, and the fifth electrode 231.

The first in-trench oxide layer 217 may surround the second electrode 212, the fourth electrode 222, and the fifth electrode 231. In some embodiments, the second electrode 212, the fourth electrode 222, and the fifth electrode 231 may be formed through physical vapor deposition (PVD), e.g., through sputtering or spraying of a semiconductor material or electrode material. In some embodiments, the second electrode 212, the fourth electrode 222, and the fifth electrode 231 may be formed through electroplating or CVD of a semiconductor material or electrode material. In some embodiments, the semiconductor material or electrode material may cover the first in-trench oxide layer 217, and then a dry etching process is performed to remove the semiconductor material or electrode material outside the first trench 210, the second trench 220 and the third trench 230 by, e.g., etching, etc., to form the second electrode 212, the fourth electrode 222, and the fifth electrode 231. Then the in-trench oxide layer 217 is formed on the top surfaces of the second electrode 212, the fourth electrode 222, and the fifth electrode 231 by thermal oxidation technology or other deposition processes. In some embodiments, the semiconductor material or electrode material includes polysilicon.

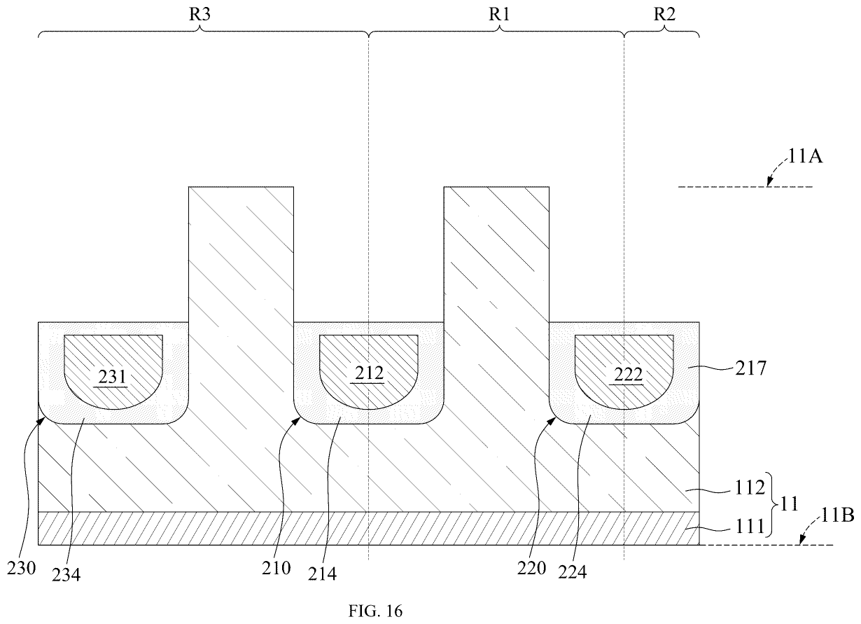

Referring to FIG. 16, the manufacturing method includes removing portions of the first in-trench oxide layer 217 in the first trench 210, the second trench 220, and the third trench 230, so as to expose the inner side surfaces of the first trench 210, the second trench 220, and the third trench 230. In some embodiments, the manufacturing method includes removing a portion of the first in-trench oxide layer 217 in the first trench 210 away from the second electrode 212, removing a portion of the first in-trench oxide layer 217 in the second trench 220 away from the fourth electrode 222, and removing a portion of the first in-trench oxide layer 217 in the third trench 230 away from the fifth electrode 231. In some embodiments, after removing the portions of the first in-trench oxide layer 217 in the first trench 210, the second trench 220 and the third trench 230, the first trench 210 includes the second electrode 212 located at the bottom of the first trench 210 and the first oxide layer 214 surrounding the second electrode 212, the second trench 220 includes the fourth electrode 222 located at the bottom of the second trench 220 and the second oxide layer 224 surrounding the fourth electrode 222, and the third trench 230 includes the fifth electrode 231 located at the bottom of the third trench 230 and the third oxide layer 234 surrounding the fifth electrode 231. The first in-trench oxide layer 217 on the first surface 11A may also be removed.

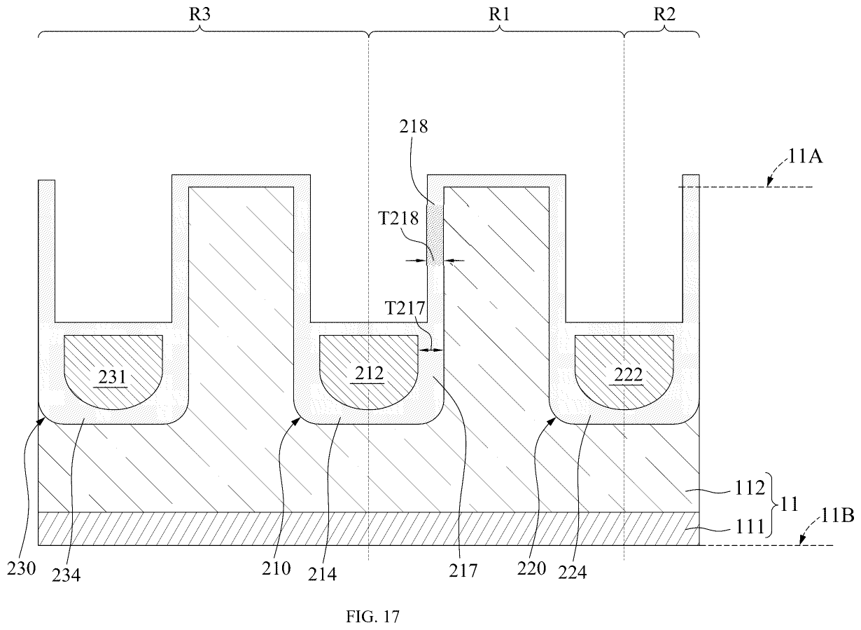

Referring to FIG. 17, the manufacturing method includes forming a second in-trench oxide layer 218 in the first trench 210, the second trench 220, and the third trench 230. In some embodiments, the second in-trench oxide layer 218 covers the first surface 11A. In some embodiments, the second in-trench oxide layer 218 may be formed by thermal oxidation technology or other deposition processes. In some embodiments, the second in-trench oxide layer 218 may be conformally deposited on the inner side surfaces (including the opposite sidewalls) of the first trench 210, the second trench 220 and the third trench 230, and on the first in-trench oxide layer 217 (i.e., the oxide layers 214, 224 and 234 that are over the second electrode 212, the fourth electrode 222 and the fifth electrode 231, respectively). In some embodiments, the second in-trench oxide layer 218 may be filled into the first trench 210, the second trench 220, and the third trench 230 through a deposition process, such that the second in-trench oxide layer 218 forms at least one groove on the second electrode 212 in the first trench 210, on the fourth electrode 222 in the second trench 220, and on the fifth electrode 231 in the third trench 230, respectively. A thickness T218 of the second in-trench oxide layer 218 is less than or equal to a thickness T217 of the first in-trench oxide layer 217. In some embodiments, a portion of the second in-trench oxide layer 218 in the first trench 210 is the first oxide layer 214, a portion of the second in-trench oxide layer 218 in the second trench 220 is the second oxide layer 224, and a portion of the second in-trench oxide layer 218 in the third trench 230 is the third oxide layer 234. As used herein, a portion of the second in-trench oxide layer 218 formed in the first trench 210 and the previous first oxide layer 214 are referred to collectively as a first oxide layer 214. Similarly, a portion of the second in-trench oxide layer 218 formed in the second trench 220 and the previous second oxide layer 224 are referred to collectively as a second oxide layer 224; and a portion of the second in-trench oxide layer 218 formed in the third trench 230 and the previous third oxide layer 234 are referred to collectively as a third oxide layer 234. This same principle applies to other oxide layers formed in the trenches in subsequent processes.

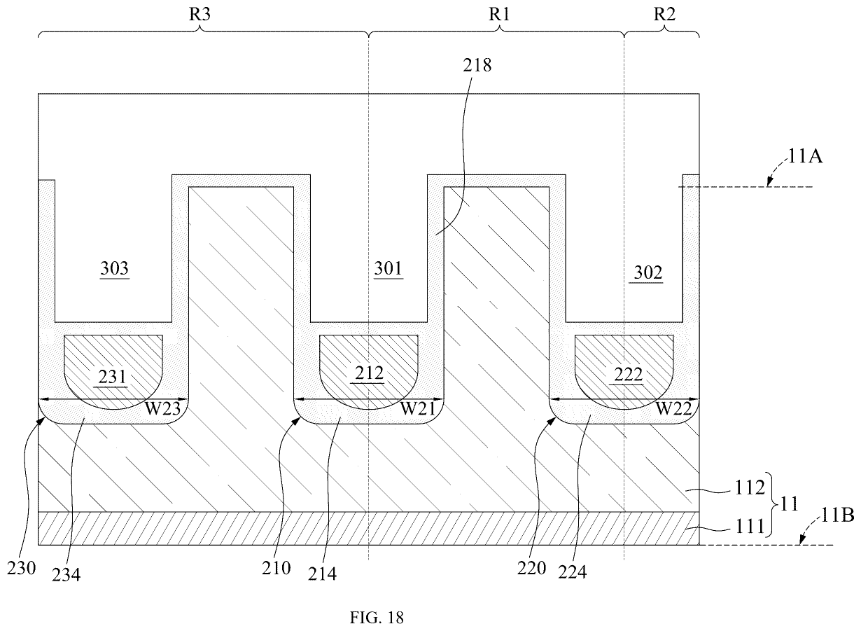

Referring to FIG. 18, the manufacturing method includes forming a first semiconductor material 301, a second semiconductor material 302, and a third semiconductor material 303 in the first trench 210, the second trench 220, and the third trench 230, respectively. In some embodiments, the first semiconductor material 301 is disposed in the first trench 210 and on the top surface of the first oxide layer 214, the second semiconductor material 302 is disposed in the second trench 220 and on the top surface of the second oxide layer 224, and the third semiconductor material 303 is disposed in the third trench 230 and on the top surface of the third oxide layer 234.

The second in-trench oxide layer 218 may surround the first semiconductor material 301, the second semiconductor material 302, and the third semiconductor material 303. In some embodiments, the first semiconductor material 301, the second semiconductor material 302, and the third semiconductor material 303 may be formed through physical vapor deposition (PVD), e.g., through sputtering or spraying of a semiconductor material. In some embodiments, the first semiconductor material 301, the second semiconductor material 302, and the third semiconductor material 303 may be formed by electroplating or CVD of a semiconductor material. In some embodiments, the first semiconductor material 301, the second semiconductor material 302, and the third semiconductor material 303 include polysilicon. In some embodiments, the semiconductor material covers the second in-trench oxide layer 218. The semiconductor material covers the second in-trench oxide layer 218 formed on the first surface 11A. In some embodiments, the semiconductor material may completely fill the space in the first trench 210, the second trench 220 and the third trench 230, extend upwardly above the first surface 11A, and reach to a position 30A.

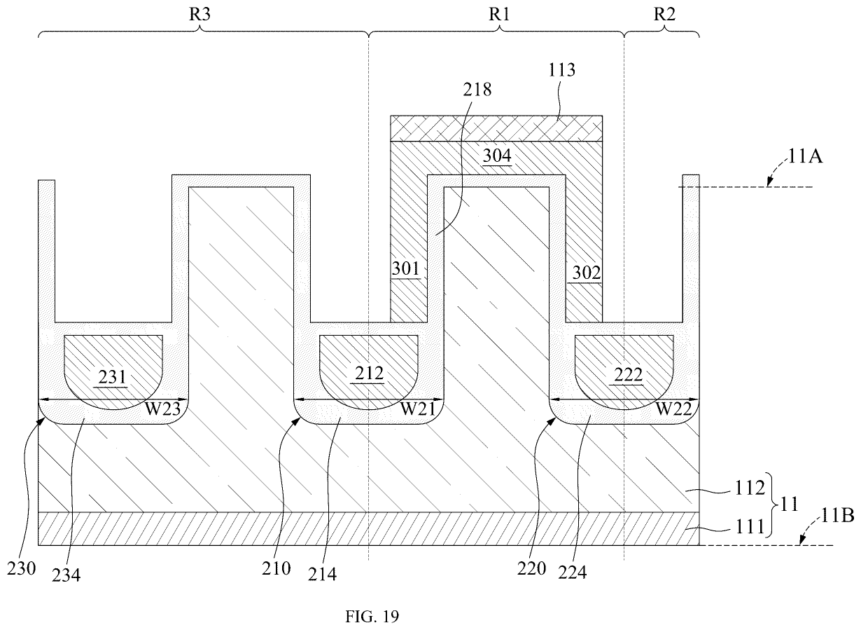

Referring to FIG. 19, the manufacturing method includes forming a second patterned shielding layer 113 as shown in FIG. 19 in the first region R1 above the epitaxial layer 112, and performing an etching process on the first semiconductor material 301, the second semiconductor material 302 and the third semiconductor material 303 through the second patterned shielding layer 113. As an example, the second patterned shielding layer 113 may be formed at the position 30A on the semiconductor material of the first, second and third semiconductor materials 301, 302 and 303. The etching process removes, from the first surface 11A, part of the first semiconductor material 301, part of the second semiconductor material 302 and the third semiconductor material 303, and the etching process stops on the top surface of the first oxide layer 214, the top surface of the second oxide layer 224 and the top surface of the third oxide layer 234, and exposes part of the second in-trench oxide layer 218 as shown in FIG. 19. According to the position defined by the second patterned shielding layer 113, a portion of the first semiconductor material 301, a portion of the second semiconductor material 302, and the semiconductor material (referred to as semiconductor material 304) located between the first trench 210 and the second trench 220 on the second in-trench oxide layer 218 are retained. In some embodiments, the retained portion of the first semiconductor material 301 and the retained portion of the second semiconductor material 302 may have vertical sidewalls parallel to the sidewalls of the trenches.

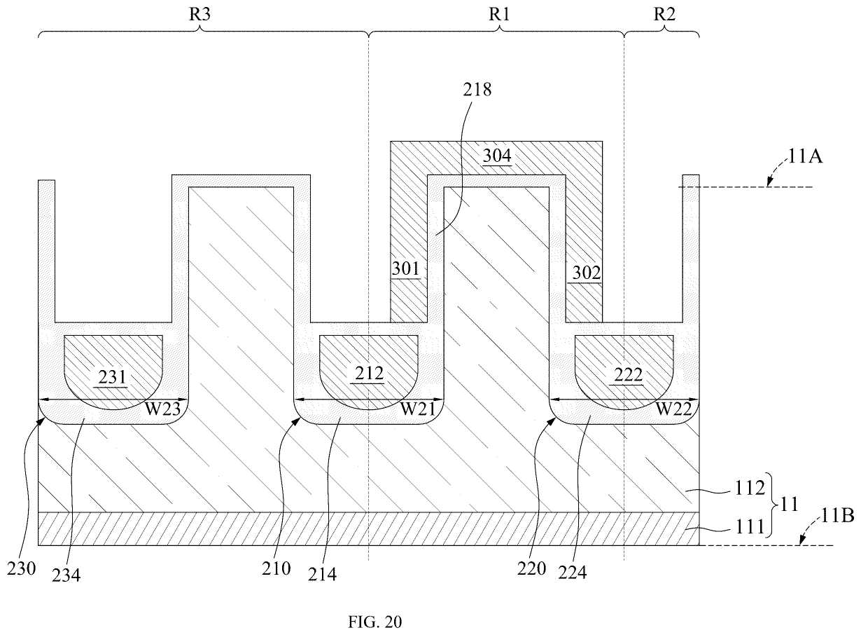

Referring to FIG. 20, the manufacturing method includes removing the second patterned shielding layer 113 to expose a portion of the top surface of the first semiconductor material 301 (i.e., a top surface of the retained portion of the first semiconductor material 301), a portion of the top surface of the second semiconductor material 302 (i.e., a top surface of the retained portion of the second semiconductor material 302), and a top surface of the semiconductor material 304 located between the first trench 210 and the second trench 220.

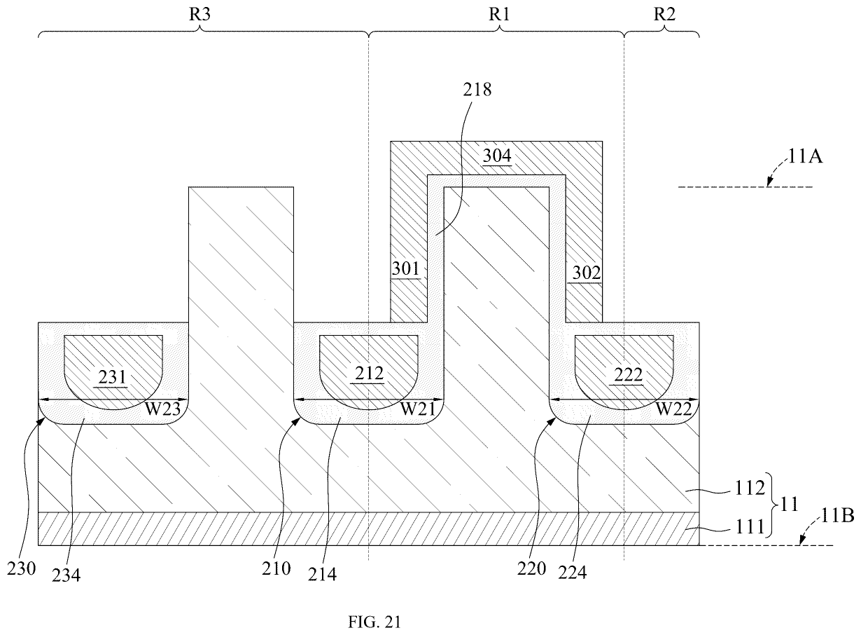

Referring to FIG. 21, the manufacturing method includes removing the second in-trench oxide layer 218 covering the first surface 11A and the inner side surfaces of the first trench 210, the second trench 220 and the third trench 230, such that a portion of the inner side surfaces of the first trench 210, a portion of the inner side surfaces of the second trench 220, and a portion of the inner side surfaces of the third trench 230 (including the opposite sidewalls) are exposed. Thus, a portion of the epitaxial layer 112 is exposed. The second in-trench oxide layer 218 may be removed by etching. In some embodiments, the manufacturing method includes removing a portion of the second in-trench oxide layer 218 located in the second region R2 and the third region R3, such that a portion of the epitaxial layer 112 is exposed; and the first oxide layer 214, the second oxide layer 224 and the third oxide layer 234 located respectively at the bottom of the first trench 210, the second trench 220 and the third trench 230 are retained. The manufacturing method includes removing a portion of the second in-trench oxide layer 218 that is not in contact with the retained portion of the first semiconductor material 301, the retained portion of the second semiconductor material 302, and the semiconductor material 304. Thus, the retained portion of the first semiconductor material 301, the retained portion of the second semiconductor material 302, and the semiconductor material 304 surrounds the remaining portion of the second in-trench oxide layer 218.

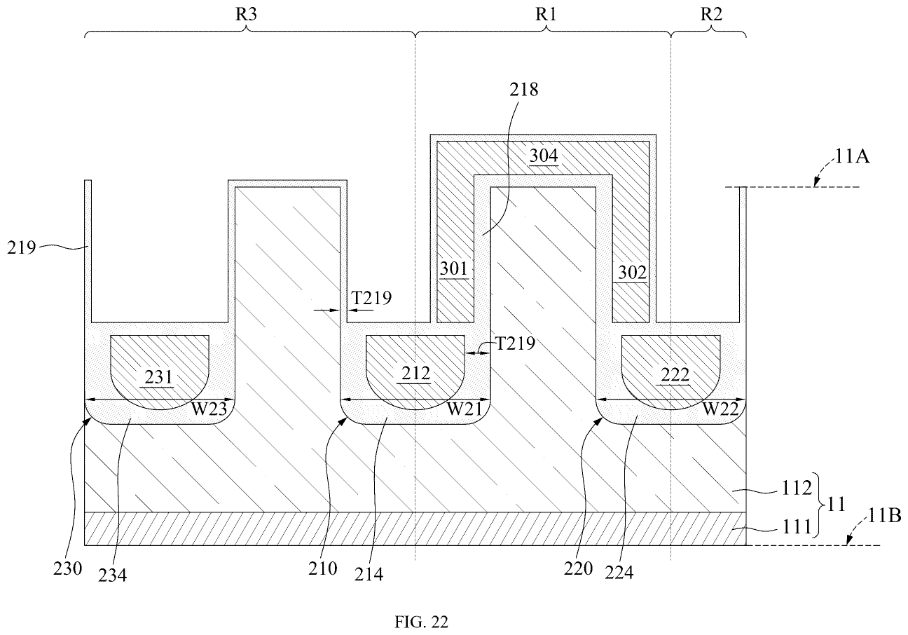

Referring to FIG. 22, the manufacturing method includes forming a third in-trench oxide layer 219 on the portion of the epitaxial layer 112 exposed in the first trench 210, the second trench 220, and the third trench 230, and forming the third in-trench oxide layer 219 on the portion of the first semiconductor material 301 retained, the portion of the second semiconductor material 302 retained, and the top surface of the semiconductor material 304 located between the first trench 210 and the second trench 220. The third in-trench oxide layer 219 covers the sidewall and the top surface of the retained portion of the first semiconductor material 301, covers the sidewall and the top surface of the retained portion of the second semiconductor material 302, and covers the top surface of the semiconductor material 304. The third in-trench oxide layer 219 is formed in the first region R1, the second region R2, and the third region R3. In some embodiments, the third in-trench oxide layer 219 covers the first surface 11A.

In some embodiments, the third in-trench oxide layer 219 may be formed by thermal oxidation technology or other deposition processes. In some embodiments, the third in-trench oxide layer 219 may be conformally deposited on the inner side surfaces (including the opposite sidewalls) of the first trench 210, the second trench 220, and the third trench 230, as well as on the first oxide layer 214, the second oxide layer 224, the third oxide layer 234, the portion of the first semiconductor material 301, the portion of the second semiconductor material 302, and the semiconductor material 304. In some embodiments, the third in-trench oxide layer 219 is used as a sacrificial structure, and the third in-trench oxide layer 219 will be removed in a subsequent step, so that surface(s) exposed after the third in-trench oxide layer 219 is removed has/have a better quality, e.g., a surface is smoother, which is conducive to forming other structures on the exposed surface.

In some embodiments, the third in-trench oxide layer 219 may be filled into the first trench 210, the second trench 220, and the third trench 230 through a deposition process, such that the third in-trench oxide layer 219 forms at least one groove, respectively, over the second electrode 212 in the first trench 210 adjacent to the portion of the first semiconductor material 301, over the fourth electrode 222 in the second trench 220 adjacent to the portion of the second semiconductor material 302, and over the fifth electrode 231 in the third trench 230. In some embodiments, a portion of the third in-trench oxide layer 219 in the first trench 210 is the first oxide layer 214, a portion of the third in-trench oxide layer 219 in the second trench 220 is the second oxide layer 224, and a portion of the third in-trench oxide layer 219 in the third trench 230 is the third oxide layer 234. In some embodiments, a thickness T219 of the third in-trench oxide layer 219 is less than the thickness T217 of the first in-trench oxide layer 217.

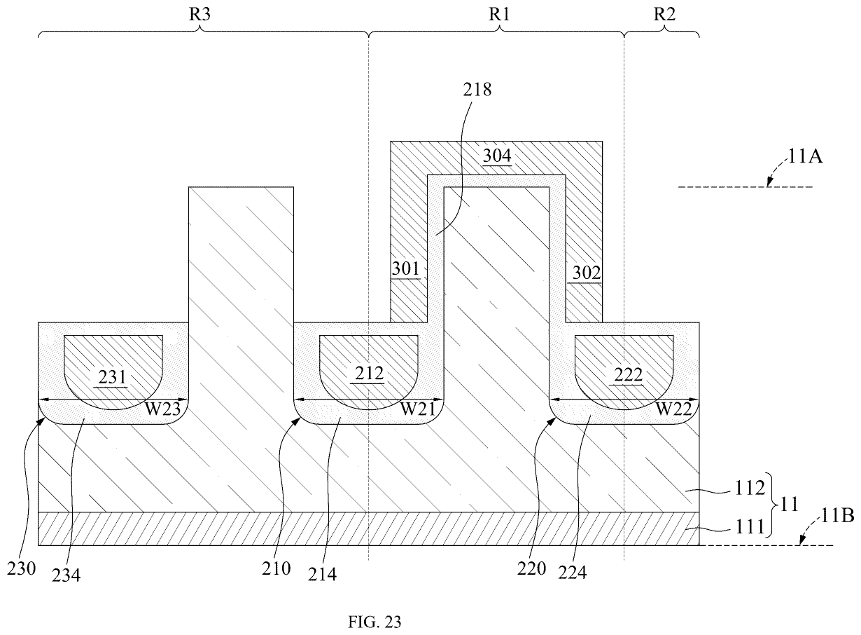

Referring to FIG. 23, the manufacturing method includes removing the third in-trench oxide layer 219. The manufacturing method includes removing the third in-trench oxide layer 219 covering the first surface 11A and located on the inner side surfaces of the first trench 210, the second trench 220, and the third trench 230, such that a portion of the inner side surface of the first trench 210, a portion of the inner side surface of the second trench 220, and the inner side surfaces of the third trench 230 (including the opposite sidewalls), as well as the portion of the first semiconductor material 301, the portion of the second semiconductor material 302, and the semiconductor material 304 are exposed. The third in-trench oxide layer 219 may be removed by using an etching method. In some embodiments, the manufacturing method includes removing the third in-trench oxide layer 219 located in the first region R1, the second region R2, and the third region R3, such that a portion of the epitaxial layer 112 is exposed, and the first oxide layer 214, the second oxide layer 224, and the third oxide layer 234 located at the bottom of the first trench 210, the second trench 220, and the third trench 230 are retained. The manufacturing method includes removing the third in-trench oxide layer 219 that is not in contact with the portion of the first semiconductor material 301, the portion of the second semiconductor material 302, and the semiconductor material 304. The epitaxial layer 112 exposed by removing the third in-trench oxide layer 219 has a relatively even surface flatness. In some embodiments, the stages shown in FIG. 22 and FIG. 23 may be omitted and are optional.

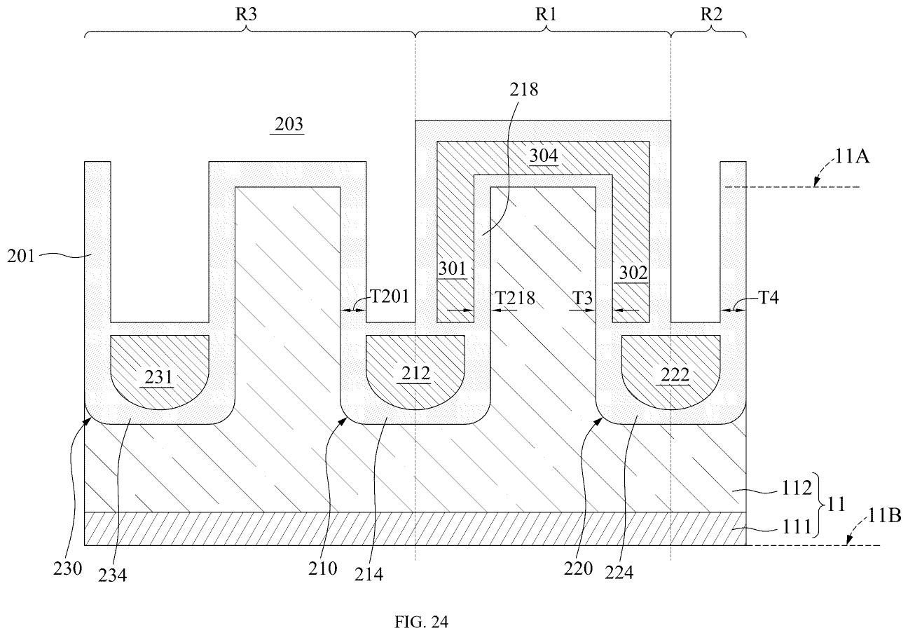

Referring to FIG. 24, the manufacturing method includes forming a fourth in-trench oxide layer 201 on the surface of the epitaxial layer 112 exposed in the first trench 210, the second trench 220 and the third trench 230, as well as the portion of the first semiconductor material 301, the portion of the second semiconductor material 302, and the semiconductor material 304 located between the first trench 210 and the second trench 220. The surface of the epitaxial layer 112 exposed in the first trench 210, the second trench 220 and the third trench 230 is basically the sidewalls of the first trench 210, the second trench 220 and the third trench 230. The fourth in-trench oxide layer 201 is formed in the first region R1, the second region R2, and the third region R3. In some embodiments, the fourth in-trench oxide layer 201 covers the first surface 11A. In some embodiments, the fourth in-trench oxide layer 201 may be formed by thermal oxidation technology or other deposition processes. In some embodiments, the fourth in-trench oxide layer 201 may be conformally deposited on the inner side surfaces (including the opposite sidewalls) of the first trench 210, the second trench 220, and the third trench 230, as well as the first oxide layer 214, the second oxide layer 224, the third oxide layer 234, the portion of the first semiconductor material 301, the portion of the second semiconductor material 302, and the semiconductor material 304. The semiconductor material 304 is located between the fourth in-trench oxide layer 201 and the second in-trench oxide layer 218.

In some embodiments, the fourth in-trench oxide layer 201 may be filled into the first trench 210, the second trench 220, and the third trench 230 through a deposition process, such that the fourth in-trench oxide layer 201 forms at least one groove, respectively, on the second electrode 212 in the first trench 210 adjacent to the portion of the first semiconductor material 301, on the fourth electrode 222 in the second trench 220 adjacent to the portion of the second semiconductor material 302, and on the fifth electrode 231 in the third trench 230. In some embodiments, a portion of the fourth in-trench oxide layer 201 in the first trench 210 is the first oxide layer 214, a portion of the fourth in-trench oxide layer 201 in the second trench 220 is the second oxide layer 224, and a portion of the fourth in-trench oxide layer 201 in the third trench 230 is the third oxide layer 234. In other words, the portion of the fourth in-trench oxide layer 201 in the first trench 210 and the previous first oxide layer 214 are combined and collectively referred to as the first oxide layer 214. Similarly, the portion of the fourth in-trench oxide layer 201 in the second trench 220 and the previous second oxide layer 224 are combined and collectively referred to as the second oxide layer 224, and the portion of the fourth in-trench oxide layer 201 in the third trench 230 and the previous third oxide layer 234 are combined and collectively referred to as the third oxide layer 234. In some embodiments, a thickness T201 of the fourth in-trench oxide layer 201 is greater than the thickness T218 of the second in-trench oxide layer 218. The thickness T201 of the fourth in-trench oxide layer 201 is greater than the thickness T219 of the third in-trench oxide layer 219 as shown in FIG. 22. In some embodiments, the thickness T218 of the second in-trench oxide layer 218 is the same as the first thickness T1 shown in FIG. 3, and the thickness T201 of the fourth in-trench oxide layer 201 is the same as the second thickness T2 shown in FIG. 3.

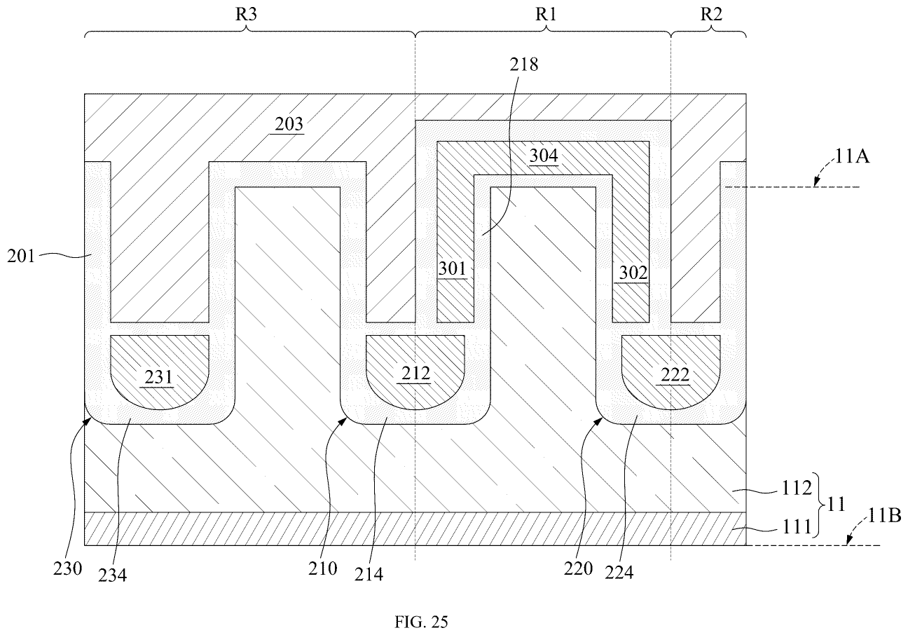

Referring to FIG. 25, the manufacturing method includes forming a fourth semiconductor material 203 on the fourth in-trench oxide layer 201. In some embodiments, the fourth semiconductor material 203 is formed in the first trench 210, the second trench 220, and the third trench 230 and on the semiconductor material 304, and covers the fourth in-trench oxide layer 201. The fourth semiconductor material 203 contacts the fourth in-trench oxide layer 201, the first oxide layer 214, the second oxide layer 224, and the third oxide layer 234.

In some embodiments, the fourth semiconductor material 203 disposed in the first trench 210 is located over the second electrode 212, adjacent to the portion of the first semiconductor material 301, and surrounded by the fourth in-trench oxide layer 201; the fourth semiconductor material 203 disposed in the second trench 220 is located over the (top surface of) the fourth electrode 222, adjacent to the portion of the second semiconductor material 302, and surrounded by the fourth in-trench oxide layer 201; and the fourth semiconductor material 203 disposed in the third trench 230 is located over the (top surface of) the fifth electrode 231 and surrounded by the fourth in-trench oxide layer 201. The fourth semiconductor material 203 is also disposed on the semiconductor material 304.

The fourth in-trench oxide layer 201 in the first trench 210, the second trench 220, and the third trench 230 surrounds the fourth semiconductor material 203. In some embodiments, the fourth semiconductor material 203 may be formed by PVD, e.g., by sputtering or spraying of a semiconductor material. In some embodiments, the fourth semiconductor material 203 may be formed by electroplating or CVD of a semiconductor material. In some embodiments, the fourth semiconductor material 203 includes polysilicon. In some embodiments, the fourth semiconductor material 203 and the first semiconductor material 301, the second semiconductor material 302, and the third semiconductor material 303 include the same or different materials.

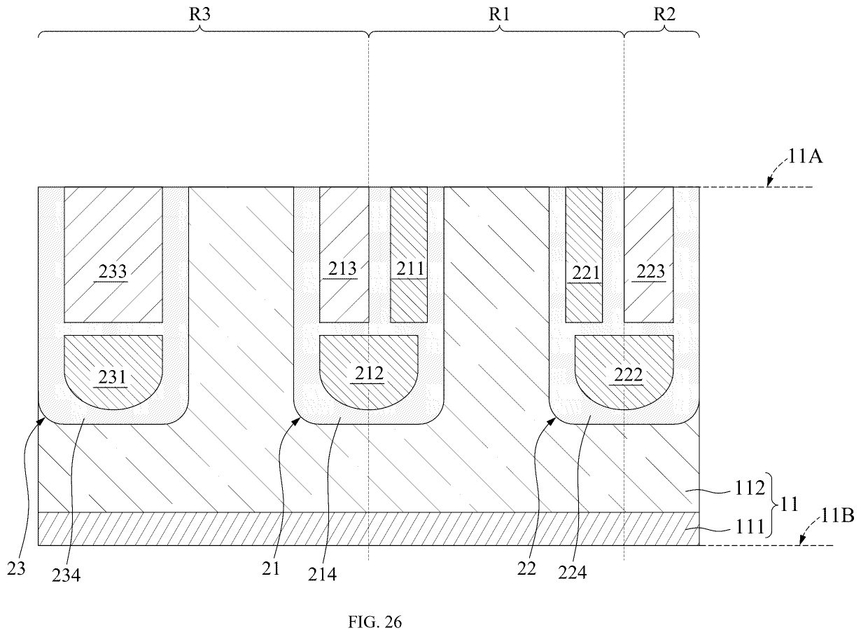

Referring to FIG. 26, the manufacturing method includes removing the semiconductor material 304, part of the fourth semiconductor material 203, part of the fourth in-trench oxide layer 201, and part of the second in-trench oxide layer 218 above the first surface 11A of the semiconductor material layer 11, to expose the first surface 11A. The first surface 11A may be ground to be smooth, for example, using a CMP process. The manufacturing method also removes part of the first semiconductor material 301 above the first surface 11A and part of the second semiconductor material 302 above the first surface 11A. In other words, the manufacturing method includes removing the structure above the first surface 11A of the semiconductor material layer 11, such that a portion of the fourth semiconductor material 203 located in the first trench 210 forms the first gate 213, and a portion of the fourth semiconductor material 203 located in the second trench 220 forms the second gate 223, and a portion of the fourth semiconductor material 203 located in the third trench 230 forms the third gate 233. The remaining first semiconductor material 301 forms the first electrode 211, and the remaining second semiconductor material 302 forms the third electrode 221.

The first electrode 211 and the third electrode 221 are formed simultaneously. The first gate 213, the second gate 223, and the third gate 233 are formed simultaneously. In some embodiments, the second electrode 212 is formed before the first electrode 211 is formed, and the fourth electrode 222 is formed before the third electrode 221 is formed. In some embodiments, the first electrode 211 is formed before the first gate 213 is formed, or the first electrode 211 and the first gate 213 are formed simultaneously. The third electrode 221 may be formed before the second gate 223 is formed, or the third electrode 221 and the second gate 223 may be formed simultaneously. The fifth electrode 231 is formed before the third gate 233 is formed.

After removing the structure above the first surface 11A of the semiconductor material layer 11, the first gate 213 is formed in the first trench 210, the first gate 213 is adjacent to the first electrode 211 and is located above the second electrode 212. The first electrode 211, the second electrode 212, the first gate 213, and the first oxide layer 214 form a first trench structure 21. In some embodiments, after removing the structure above the first surface 11A of the semiconductor material layer 11, the second gate 223 is formed in the second trench 220, the second gate 223 is adjacent to the third electrode 221 and is located above the fourth electrode 222. The third electrode 221, the fourth electrode 222, the second gate 223, and the second oxide layer 224 form a second trench structure 22. In some embodiments, after removing the structure above the first surface 11A of the semiconductor material layer 11, the third gate 233 is formed in the third trench 230, the third gate 233 is located above the fifth electrode 231, and the third gate 233, the fifth electrode 231 and the third oxide layer 234 form a third trench structure 23. The manufacturing method includes removing the structure above the first surface 11A of the semiconductor material layer 11, such that the first trench structure 21, the second trench structure 22, and the third trench structure 23 are exposed.

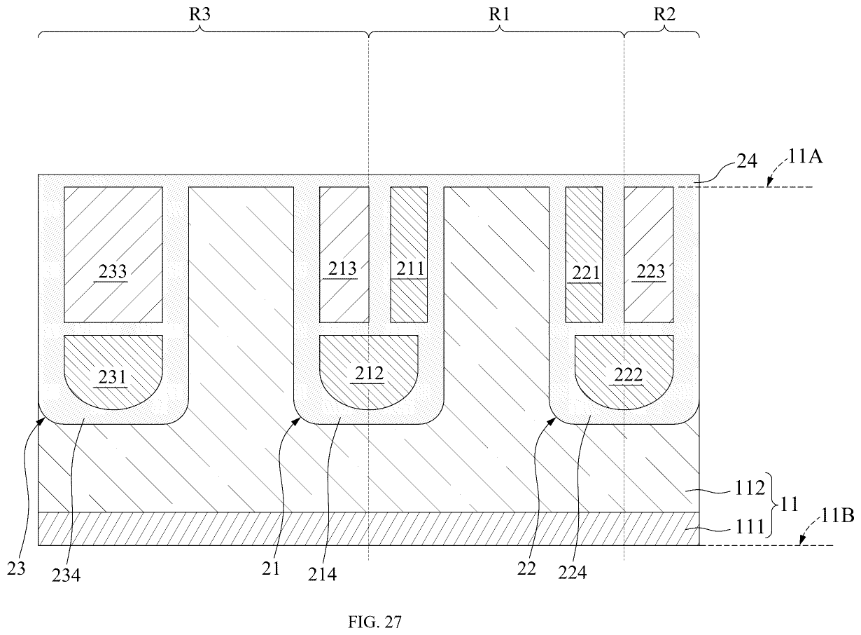

Referring to FIG. 27, the manufacturing method includes forming a fourth oxide layer 24 on the first surface 11A of the semiconductor material layer 11, the first trench structure 21, the second trench structure 22, and the third trench structure 23. The fourth oxide layer 24 is in contact with the first surface 11A of the semiconductor material layer 11, the first trench structure 21, the second trench structure 22, and the third trench structure 23. In some embodiments, the fourth oxide layer 24 may be formed by the thermal oxidation technology or other deposition processes.

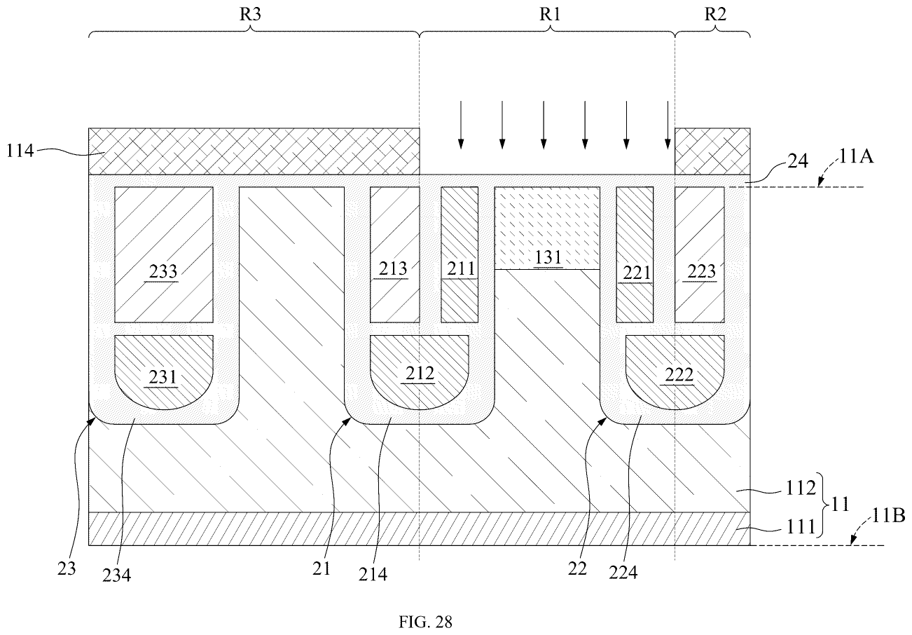

Referring to FIG. 28, the manufacturing method includes forming a first doped region 131 in the semiconductor material layer 11 between the first trench structure 21 and the second trench structure 22, and the first doped region 131 has the second conductivity type. The first doped region 131 may be formed in the epitaxial layer 112 by diffusion or ion implantation from the first surface 11A, and ions are implanted into the first surface 11A along the vertical direction Z. The first doped region 131 is formed in the first region R1, and the depth of the first doped region 131 is less than the depths of the first trench structure 21, the second trench structure 22 and the third trench structure 23. In other words, the bottom of the first doped region 131 is higher than the bottoms of the first trench structure 21, the second trench structure 22 and the third trench structure 23. In some embodiments, an annealing process is performed to the first doped region 131 after the first doped region 131 is formed by the ion implantation process, to diffuse the doping ions of the first doped region 131. In some embodiments, the doping ions are, for example, boron ions, aluminum ions, gallium ions, indium ions, and so on. In some embodiments, boron ions are implanted into the first doped region 131.

In some embodiments, a third patterned shielding layer 114 is formed on the fourth oxide layer 24 to define the position of the first doped region 131, and the conductivity type and depth of the first doped region 131 are defined by adjusting the ions, energy and dosage of the diffusion or ion implantation process. In some embodiments, the third patterned shielding layer 114 is formed by performing a photolithography process using a photomask having a corresponding pattern. As shown in FIG. 28, the third patterned shielding layer 114 is formed on the fourth oxide layer 24 in the second region R2 and the third region R3, with an opening formed in the first region R1. The opening extends over the first doped region 131, part of the first trench structure 21 and part of the second trench structure 22.

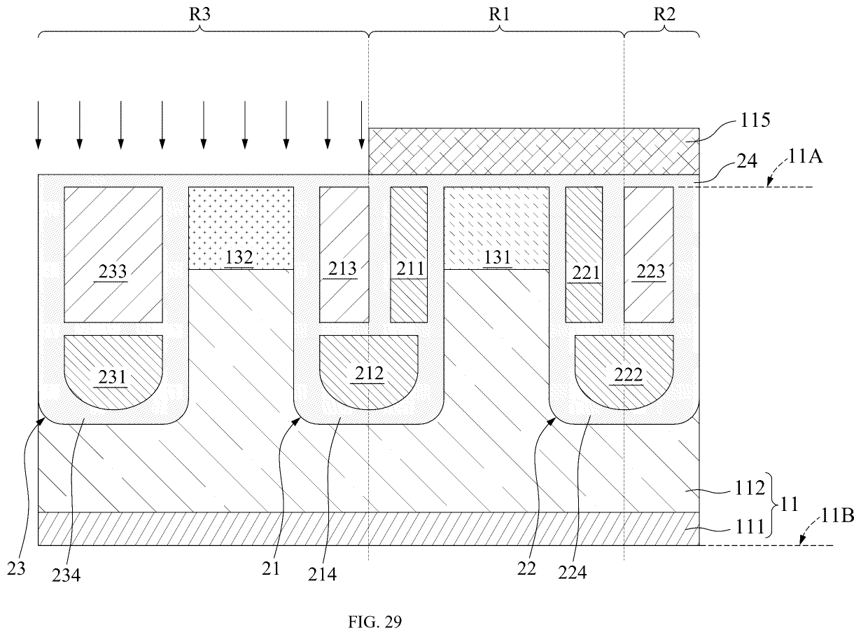

Referring to FIG. 29, the manufacturing method includes forming a third doped region 132 in the semiconductor material layer 11 between the second trench structure 22 and the third trench structure 23, and the third doped region 132 has the second conductivity type. The third doped region 132 may be formed in the epitaxial layer 112 by diffusion or ion implantation from the first surface 11A, and ions are implanted into the first surface 11A along the vertical direction Z. The third doped region 132 is formed in the second region R2 or the third region R3, and the depth of the third doped region 132 is less than the depths of the first trench structure 21, the second trench structure 22, and the third trench structure 23. In other words, the bottom of the third doped region 132 is higher than the bottoms of the first trench structure 21, the second trench structure 22, and the third trench structure 23. In some embodiments, an annealing process is performed to third doped region 132 after the third doped region 132 is formed by the ion implantation process, to diffuse the doped ions of the third doped region 132. In some embodiments, the doping ions are, for example, boron ions, aluminum ions, gallium ions, indium ions, and so on. In some embodiments, boron ions are implanted into the third doped region 132.

In some embodiments, a fourth patterned shielding layer 115 is formed on the fourth oxide layer 24 to define the position of the third doped region 132, and the conductivity type and depth of the third doped region 132 are defined by adjusting the ions, energy and dosage of the diffusion or ion implantation process. In some embodiments, the fourth patterned shielding layer 115 is formed by a photolithography process using a photomask having a corresponding pattern. The first doped region 131 and the third doped region 132 are formed separately and have the same or different doping concentrations. In some embodiments, the first doped region 131 is formed before the third doped region 132 is formed.

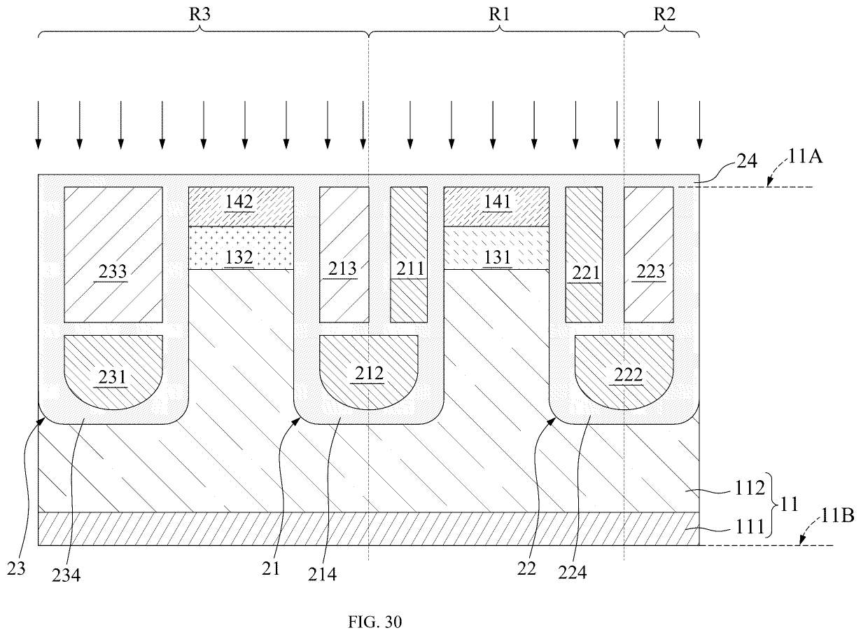

Referring to FIG. 30, the manufacturing method includes forming a second doped region 141 in the first doped region 131 and adjacent to a portion of the first surface 11A of the semiconductor material layer 11, and forming a fourth doped region 142 in the third doped region 132 and adjacent to a portion of the first surface 11A of the semiconductor material layer 11, where the second doped region 141 and the fourth doped region 142 are heavily doped regions having the first conductivity type. The second doped region 141 is formed between the first doped region 131 and the fourth oxide layer 24, and the fourth doped region 142 is formed between the third doped region 132 and the fourth oxide layer 24.

The second doped region 141 and the fourth doped region 142 may be formed in the epitaxial layer 112 by diffusion or ion implantation from the first surface 11A, and ions are implanted into the first surface 11A along the vertical direction Z. The second doped region 141 is formed in the first region R1, the fourth doped region 142 is formed in the second region R2 or the third region R3. The depths of the second doped region 141 and the fourth doped region 142 are respectively less than the depths of the first doped region 131 and the third doped region 132. In other words, the bottom of the second doped region 141 is higher than the bottom of the first doped region 131, and the bottom of the fourth doped region 142 is higher than the bottom of the third doped region 132. In some embodiments, an annealing process is performed after the second doped region 141 and the fourth doped region 142 are formed by the ion implantation process, to diffuse the doped ions. In some embodiments, the second doped region 141 and the fourth doped region 142 are formed simultaneously. In some embodiments, the top surfaces of the second doped region 141 and the fourth doped region 142 may be coplanar with the first surface.

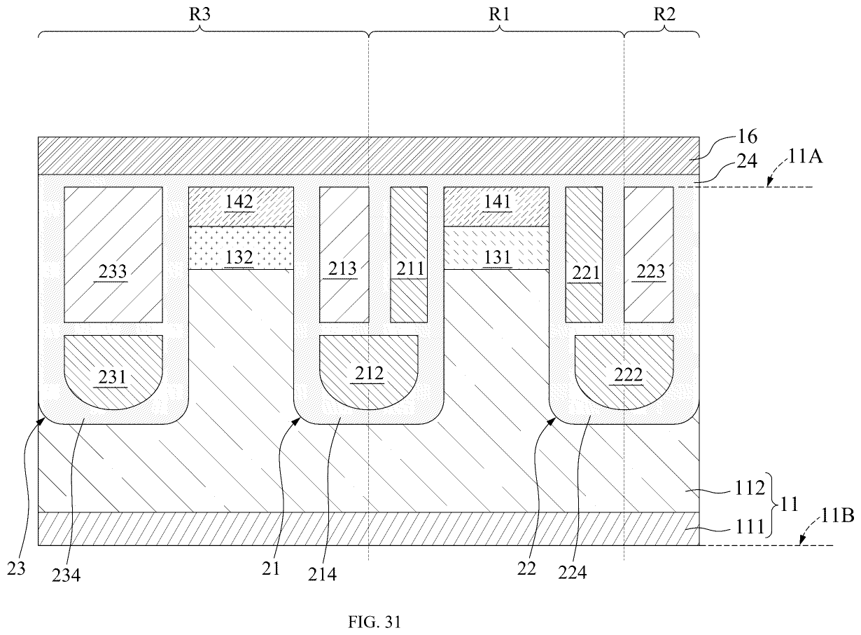

Referring to FIG. 31, the manufacturing method includes forming an interlayer dielectric layer 16 over the first surface 11A of the semiconductor material layer 11, and the interlayer dielectric layer 16 covers the first trench structure 21, the second trench structure 22, the third trench structure 23, the second doped region 141, and the fourth doped region 142. The manufacturing method includes forming the interlayer dielectric layer 16 on the fourth oxide layer 24. The interlayer dielectric layer 16 may be formed by the thermal oxidation technology or other deposition processes.

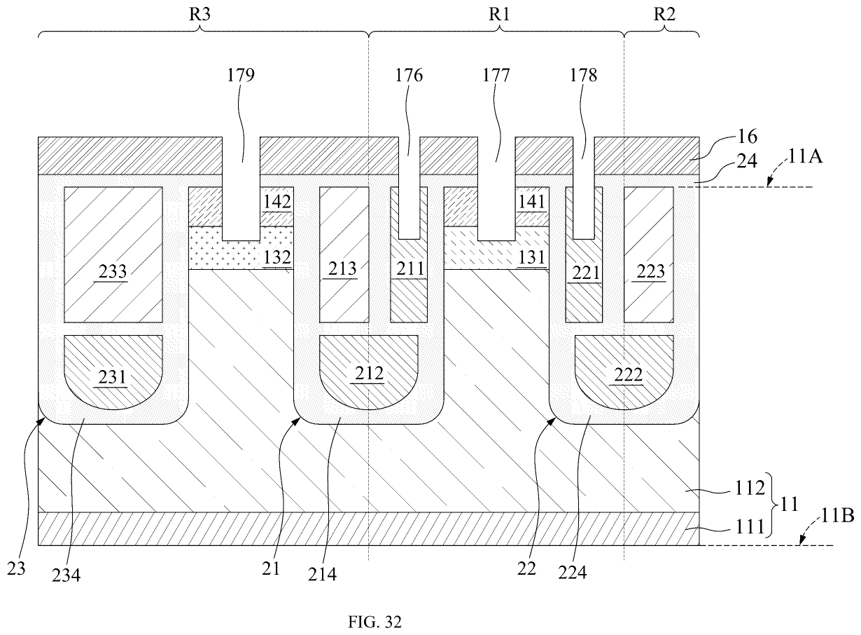

Referring to FIG. 32, the manufacturing method includes partially removing the interlayer dielectric layer 16 and the fourth oxide layer 24, and partially removing the epitaxial layer 112, the first electrode 211 and the third electrode 221 to form a first opening 176, a second opening 177, a third opening 178, and a fourth opening 179. The first opening 176, the second opening 177, the third opening 178, and the fourth opening 179 may be formed by one or more etching processes. The first opening 176 and the third opening 178 are located on the electrode structure in the first region R1, respectively exposing a portion of the first electrode 211 and a portion of the third electrode 221. The first opening 176 and the third opening 178 are located in the first region R1 and are spaced apart, and may have approximately the same width and approximately the same depth. The first opening 176 extends through the interlayer dielectric layer 16 and the fourth oxide layer 24 into the first electrode 211. The third opening 178 extends through the interlayer dielectric layer 16 and the fourth oxide layer 24 into the third electrode 221.

The second opening 177 is located between the adjacent first trench structure 21 and the second trench structure 22, passes through the second doped region 141 and stops in the first doped region 131. The fourth opening 179 is located between the first trench structure 21 and the third trench structure 23, passes through the fourth doped region 142 and stops in the third doped region 132. In some embodiments, the second opening 177 is located in the second region R2, and the fourth opening 179 is located in the third region R3. The second opening 177 may have approximately the same width and approximately the same depth as the fourth opening 179. The width of the first opening 176 or the third opening 178 may be different from the width of the second opening 177 or the fourth opening 179. In some embodiments, the width of the first opening 176 or the third opening 178 is less than the width of the second opening 177 or the fourth opening 179.

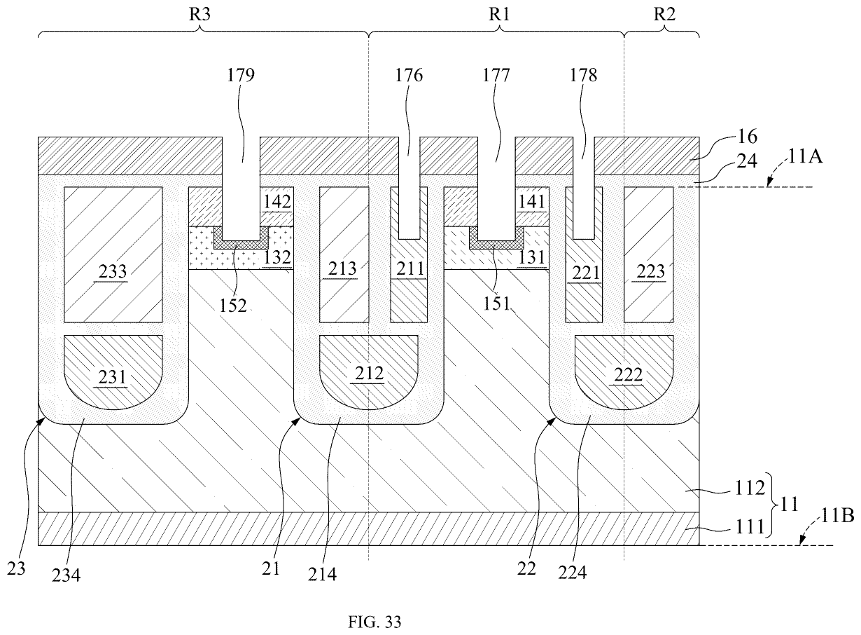

Referring to FIG. 33, the manufacturing method includes performing an ion implantation process on the epitaxial layer 112 through the second opening 177 and the fourth opening 179 to form a heavily doped region 151 in the first region R1 and a heavily doped region 152 in the second region R2 or the third region R3. Ions are implanted into the epitaxial layer 112 at the bottom of the second opening 177 and the bottom of the fourth opening 179 along the vertical direction Z. The heavily doped regions 151 and 152 are respectively formed in the epitaxial layer 112 adjacent to the bottom of the second opening 177 and the bottom of the fourth opening 179. In some embodiments, an annealing process is performed after the ion implantation process to form the heavily doped regions 151 and 152 shown in FIG. 33.

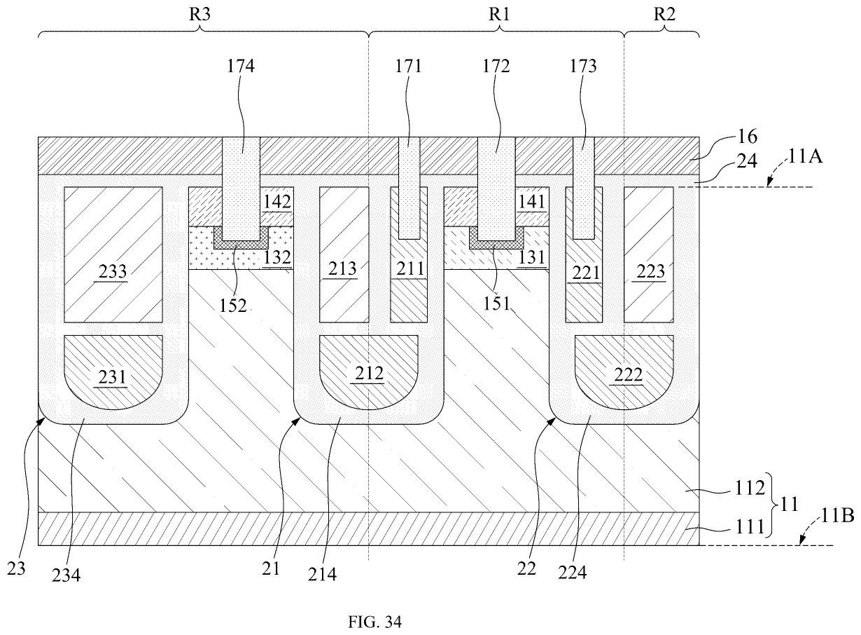

Referring to FIG. 34, the manufacturing method includes forming a first conductive plug 171 in the first opening 176, a second conductive plug 172 in the second opening 177, a third conductive plug 173 in the third opening 178, and a fourth conductive plug 174 in the fourth opening 179. The first conductive plug 171, the second conductive plug 172, the third conductive plug 173, and the fourth conductive plug 174 may be formed by electroplating or CVD to fill with a conductive material the first opening 176, the second opening 177, the third opening 178, and the fourth opening 179, respectively. The first conductive plug 171, the second conductive plug 172, the third conductive plug 173, and the fourth conductive plug 174 may be formed simultaneously or separately, and the material used may include gold (Au), silver (Ag), copper (Cu), platinum (Pt), palladium (Pd), tungsten (W), titanium (Ti), tantalum (Ta), molybdenum (Mo) or other metals or alloys. In some embodiments, a planarization process may be optionally performed after the electroplating or CVD. As a result, in some embodiments, the top surfaces of the first conductive plug 171, the second conductive plug 172, the third conductive plug 173, and the fourth conductive plug 174 are flush or located at approximately the same level.

The configurations of the first conductive plug 171, the second conductive plug 172, the third conductive plug 173, and the fourth conductive plug 174 are defined by the configurations of the first opening 176, the second opening 177, the third opening 178 and the fourth opening 179, respectively, and thus, have the same configurations as the first opening 176, the second opening 177, the third opening 178 and the fourth opening 179, respectively. The first conductive plug 171 contacts the first electrode 211 in the first region R1. The second conductive plug 172 contacts the second doped region 141 and the heavily doped region 151 or the first doped region 131 in the first region R1. The third conductive plug 173 contacts the third electrode 221 in the first region R1, and the fourth conductive plug 174 contacts the fourth doped region 142 and the heavily doped region 152 or the third doped region 132 in the third region R3.

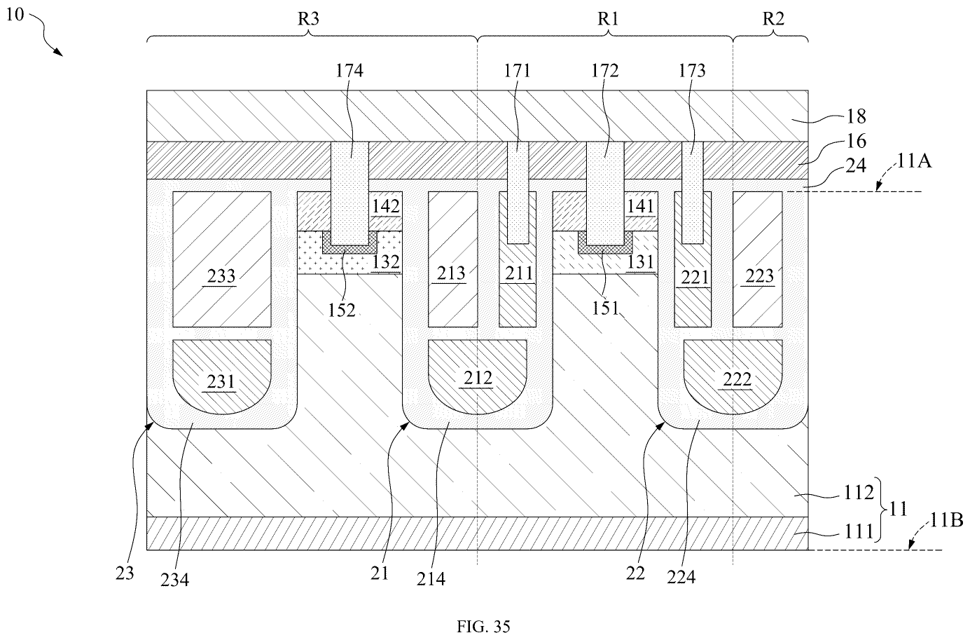

Referring to FIG. 35, the manufacturing method includes forming a metal layer 18 on the interlayer dielectric layer 16. As a result, the manufacturing method forms a trench semiconductor structure 10. The metal layer 18 may be formed by electroplating or CVD, and the metal layer 18 may be patterned according to electrical properties and operating requirements. The material of the metal layer 18 may include copper (Cu), gold (Au), silver (Ag), aluminum (Al), nickel (Ni), titanium (Ti), tungsten (W), tin (Sn) or other metals or alloy. In some embodiments, an etching process is used to define the metal layer 18 as a plurality of metal wires. In some embodiments, the metal layer 18 is in contact with the interlayer dielectric layer 16 and is electrically connected to the first conductive plug 171, the second conductive plug 172, the third conductive plug 173 and the fourth conductive plug 174. The first conductive plug 171, the second conductive plug 172, the third conductive plug 173 and the fourth conductive plug 174 extend from the metal layer 18 along the vertical direction Z. The first conductive plug 171 is formed between the first trench structure 21 and the metal layer 18, the second conductive plug 172 is formed between the first doped region 131 and the metal layer 18, the third conductive plug 173 is formed between the second trench structure 22 and the metal layer 18, and the fourth conductive plug 174 is formed between the third doped region 132 and the metal layer 18.

The trench semiconductor structure 10 formed through the above steps of the manufacturing method may be substantially the same as the trench semiconductor structure 10 shown in FIGS. 1 to 12. The trench semiconductor structure 10 has the first trench structure 21 including the first electrode 211 and the first gate 213, and the second trench structure 22 including the third electrode 221 and the second gate 223. The first doped region 131 and the second doped region 141 are disposed between the first electrode 211 and the third electrode 221. The first electrode 211, the third electrode 221, the first doped region 131 and the second doped region 141 form an SBR, and the SBR is integrated with the SGT MOSFET of the trench semiconductor structure 10, which improves the chip area utilization rate and achieves the effect of effective use of space.

The following provides some further embodiments.

In one embodiment, a trench semiconductor structure includes: a semiconductor material layer having a first surface and a second surface opposite to the first surface, wherein the semiconductor material layer has a first conductivity type; a first trench structure extending from the first surface toward the second surface, wherein the first trench structure includes a first electrode, a first gate adjacent to the first electrode, a second electrode located below the first electrode and the first gate, and a first oxide layer separating the first electrode, the second electrode, and the first gate from each other; a first doped region, located in the semiconductor material layer, close to the first surface, and adjacent to the first trench structure, wherein the first doped region has a second conductivity type; a second doped region, located between the first surface and the first doped region, wherein the second doped region has the first conductivity type; an interlayer dielectric layer, located on the first surface of the semiconductor material layer and covering the first trench structure and the second doped region; and a metal layer, located on the interlayer dielectric layer, wherein the first electrode is located between the first gate and the first doped region, and the first electrode and the first doped region are electrically connected to the metal layer.

Optionally, in the previous embodiment, the trench semiconductor structure may further include: a second trench structure extending from the first surface toward the second surface and disposed adjacent to the first trench structure, wherein the second trench structure comprises a third electrode, a second gate adjacent to the third electrode, a fourth electrode located below the third electrode and the second gate, and a second oxide layer separating the third electrode, the fourth electrode and the second gate from each other, wherein the third electrode is located between the second gate and the first doped region.

Optionally, in any of the previous embodiments, a trench depth of the first trench structure is same as a trench depth of the second trench structure, and a trench width of the first trench structure is same as a trench width of the second trench structure.

Optionally, in any of the previous embodiments, the first electrode, the third electrode, the first doped region and the second doped region form a super barrier rectifier (SBR).

Optionally, in any of the previous embodiments, a width of the first gate is greater than a width of the first electrode.

Optionally, in any of the previous embodiments, the trench semiconductor structure may further include: a first conductive plug, electrically connecting the first electrode and the metal layer; and a second conductive plug, at least partially surrounded by the first doped region and electrically connected to the metal layer.

Optionally, in any of the previous embodiments, the trench semiconductor structure may further include: a third trench structure extending from the first surface toward the second surface and disposed adjacent to the first trench structure, wherein the third trench structure comprises a fifth electrode, a third gate located above the fifth electrode, and a third oxide layer separating the fifth electrode and the third gate from each other; and a third doped region, located in the semiconductor material layer close to the first surface, and between the first trench structure and the third trench structure, wherein the third doped region has the second conductivity type, and the first trench structure is located between the first doped region and the third doped region.

Optionally, in any of the previous embodiments, a doping concentration of the third doped region is different from a doping concentration of the first doped region.

Optionally, in any of the previous embodiments, a width of the third trench structure is smaller than a width of the first trench structure.

Optionally, in any of the previous embodiments, the trench semiconductor structure may further include a fourth conductive plug at least partially surrounded by the third doped region and electrically connected to the metal layer.

Optionally, in any of the previous embodiments, the fourth conductive plug extends through the third doped region.

Optionally, in any of the previous embodiments, the first oxide layer located between the first electrode and the semiconductor material layer has a first thickness, the first oxide layer located between the first gate and the semiconductor material layer has a second thickness, and the second thickness is greater than the first thickness.

Optionally, in any of the previous embodiments, the trench semiconductor structure may further include a fourth oxide layer located on the first surface of the semiconductor material layer and between the interlayer dielectric layer, the first trench structure and the second doped region.

In another embodiment, a trench semiconductor structure includes: a semiconductor material layer, the semiconductor material layer having a first conductivity type, and having a first region and a second region surrounding the first region; a first trench structure, recessed into the semiconductor material layer, and comprising a first electrode, a first gate, and a first oxide layer surrounding the first electrode and the first gate; a second trench structure, recessed into the semiconductor material layer, and comprising a second electrode, a second gate, and a second oxide layer surrounding the second electrode and the second gate; and a first doped region disposed in the semiconductor material layer and between the first trench structure and the second trench structure, wherein the first doped region has a second conductivity type, wherein the first electrode and the second electrode are disposed between the first gate and the second gate, the first electrode, the second electrode, and the first doped region between the first electrode and the second electrode are located in the first region, and the first gate and the second gate are located in the second region.

Optionally, in the previous embodiment, the first region comprises a super barrier rectifier (SBR), and the second region comprises a shielded gate trench metal oxide semiconductor field effect transistor (SGT MOSFET).

Optionally, in any of the previous embodiments, the first trench structure further includes a third electrode, at least a portion of the first gate is located between the first electrode and the third electrode, and the first oxide layer surrounds the first electrode, the third electrode and the first gate, and separates the first electrode, the third electrode and the first gate from each other.

Optionally, in any of the previous embodiments, the semiconductor material layer has a third region adjacent to the second region and different from the first region, and the third electrode is located in the third region.

Optionally, in any of the previous embodiments, a length of the first electrode is same as or different from a length of the second electrode when viewed from a top view.

In yet another embodiment, a manufacturing method of a trench semiconductor structure includes: forming a first trench in a semiconductor material layer, wherein the first trench and a second trench extend from a first surface toward a second surface; forming, in the first trench, a first electrode and a second electrode located below the first electrode; forming a first gate in the first trench, wherein the first gate is adjacent to the first electrode and is located above the second electrode, and the first electrode, the second electrode and the first gate form a first trench structure; forming a first doped region in the semiconductor material layer, wherein the first doped region has a second conductivity type, and the first electrode is located between the first doped region and the first gate; forming a second doped region in the first doped region and adjacent to a portion of the first surface of the semiconductor material layer, the second doped region being a heavily doped with the first conductivity type; forming an interlayer dielectric layer on the first surface of the semiconductor material layer, wherein the interlayer dielectric layer covers the first trench structure and the second doped region; and forming a metal layer on the interlayer dielectric layer, wherein the first electrode and the first doped region are both electrically connected to the metal layer.

Optionally, in the previous embodiment, the manufacturing method may further include: forming a first conductive plug between the first trench structure and the metal layer, wherein the first conductive plug extends from the metal layer and contacts the first electrode; and forming a second conductive plug between the first doped region and the metal layer, wherein the second conductive plug extends from the metal layer, passes through the second doped region, and contacts the first doped region.

Optionally, in any of the previous embodiments, the manufacturing method may further include: forming the second trench in the semiconductor material layer, wherein the second trench extends from the first surface toward the second surface and is disposed adjacent to the first trench; forming, in the second trench, a third electrode and a fourth electrode below the third electrode; forming a second gate in the second trench, wherein the second gate is adjacent to the third electrode and is located above the fourth electrode, and the third electrode, the fourth electrode and the second gate form a second trench structure; and forming a third conductive plug between the second trench structure and the metal layer, wherein the third conductive plug extends from the metal layer and contacts the third electrode, the first doped region is between the first trench structure and the second trench structure, and the interlayer dielectric layer covers the second trench structure.

Optionally, in any of the previous embodiments, forming the first trench structure in the first trench and forming the second trench structure in the second trench further comprises: forming a first oxide layer in the first trench, wherein the first electrode, the second electrode, and the first gate are surrounded by the first oxide layer and separated from each other; and forming a second oxide layer in the second trench, wherein the third electrode, the fourth electrode and the second gate are surrounded by the second oxide layer and separated from each other.

Optionally, in any of the previous embodiments, the manufacturing method may further include: forming a third trench in the semiconductor material, the third trench extending from the first surface toward the second surface, and the first trench being located between the third trench and the second trench; and forming a fifth electrode, a third gate located on the fifth electrode, and a third oxide layer surrounding the fifth electrode and the third gate and separating them from each other, wherein the fifth electrode, the third gate and the third oxide layer form a third trench structure, and the first trench structure is located between the second trench structure and the third trench structure.

Optionally, in any of the previous embodiments, the manufacturing method may further include: forming a third doped region in the semiconductor material layer, wherein the first gate is located between the third doped region and the first electrode, and the third doped region has the second conductivity type; forming a fourth doped region in a portion of the third doped region adjacent to the first surface of the semiconductor material layer, wherein the fourth doped region is a heavily doped region having the first conductivity type; and forming a fourth conductive plug between the third doped region and the metal layer, wherein the fourth conductive plug extends from the metal layer, passes through the fourth doped region, and contacts the third doped region.

Optionally, in any of the previous embodiments, the first doped region is formed before the third doped region is formed.

Optionally, in any of the previous embodiments, the first conductive plug and the second conductive plug are formed simultaneously.

Optionally, in any of the previous embodiments, the second electrode is formed before the first electrode is formed, and the first electrode is formed before the first gate is formed.

Optionally, in any of the previous embodiments, the first electrode and the third electrode are formed simultaneously, and the second electrode and the fourth electrode are formed simultaneously.

Optionally, in any of the previous embodiments, the manufacturing method may further include: forming a fourth oxide layer on the first surface of the semiconductor material layer, wherein the fourth oxide layer is located between the interlayer dielectric layer and the first trench structure and between the interlayer dielectric layer and the second doped region

According to the structure and process of the present disclosure described above, under the same purpose and concept, the steps in the above process may be adjusted or orders of the steps may be changed to achieve the same or similar semiconductor structure.

In this disclosure, for description convenience, spatially relative terms such as “below”, “under”, “lower”, “above”, “upper”, “left side”, “right side”, and the like, may be used to describe the relationship of one component or feature with another one or more components or features, as shown in the accompanying drawings. The spatially relative terms are not only used to depict the orientations in the accompanying drawings, but also intended to encompass different orientations of a device in use or operation. A device may be oriented in other ways (rotated 90 degrees or in other orientations), and the spatially relative terms used herein may be interpreted in a corresponding way similarly. It should be understood that when a component is referred to as being “connected to” or “coupled to” another component, it may be directly connected or coupled to another component or an intervening component may be present.

As used herein, the terms “approximately”, “basically”, “substantially” and “about” are used to describe and account for small variations. When used in conjunction with an event or instance, the terms may refer to an embodiment of exact occurrence of an event or instance as well as an embodiment where the event or instance is close to occurrence. As used herein with respect to a given value or range, the term “about” generally means being within ±10%, ±5%, ±1%, or ±0.5% of the given value or range. A range herein may be referred to as being from one endpoint to the other or as being between two endpoints. All ranges disclosed herein are inclusive of the endpoints unless otherwise indicated. The term “substantially coplanar” may mean that the difference of positions of two surfaces with reference to the same plane is within a few micrometers (μm), e.g., within 10 μm, within 5 μm, within 1 μm, or within 0.5 μm. When values or characteristics are referred to as being “substantially” the same, the term may refer to a value that is within ±10%, ±5%, ±1%, or ±0.5% of the mean of the values.

The foregoing summarizes the features of several embodiments and detailed aspects of the present disclosure. The embodiments described in the present disclosure may be readily used as a basis for designing or modifying other processes and structures to facilitate the implementation of the same or similar purposes and/or to achieve the same or similar advantages of the embodiments presented herein. Such equivalent constructions do not depart from the spirit and scope of the present disclosure, and various changes, substitutions and modifications may be made without departing from the spirit and scope of the present disclosure. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. A trench semiconductor structure, comprising:
a semiconductor material layer of a first conductivity type, the semiconductor material layer having a first surface and a second surface opposite to the first surface;
a first trench structure extending from the first surface toward the second surface, wherein the first trench structure includes a first electrode, a first gate, a second electrode located below the first electrode and the first gate, and a first oxide layer separating the first electrode, the second electrode and the first gate from each other;
a first doped region of a second conductivity type in the semiconductor material layer, wherein the first electrode is between the first gate and the first doped region;
a second doped region of the first conductivity type, located between the first surface and the first doped region; and
an interlayer dielectric layer over the first surface of the semiconductor material layer and covering the first trench structure and the second doped region; and
a metal layer, located on the interlayer dielectric layer, wherein the first electrode and the first doped region are electrically connected to the metal layer.

2. The trench semiconductor structure of claim 1, further comprising:
a second trench structure extending from the first surface toward the second surface, wherein the second trench structure comprises a third electrode, a second gate, a fourth electrode located below the third electrode and the second gate, and a second oxide layer separating the third electrode, the fourth electrode and the second gate from each other,
wherein the third electrode is located between the second gate and the first doped region.

3. The trench semiconductor structure of claim 2, wherein a trench depth of the first trench structure is same as a trench depth of the second trench structure, and a trench width of the first trench structure is same as a trench width of the second trench structure.

4. The trench semiconductor structure of claim 1, wherein the first electrode, the third electrode, the first doped region and the second doped region form a super barrier rectifier (SBR).

5. The trench semiconductor structure of claim 1, further comprising:
a first conductive plug, electrically connecting to the first electrode and the metal layer; and
a second conductive plug, at least partially surrounded by the first doped region and electrically connected to the metal layer.

6. The trench semiconductor structure of claim 1, further comprising:
a third trench structure extending from the first surface toward the second surface, wherein the third trench structure comprises a fifth electrode, a third gate located above the fifth electrode, and a third oxide layer separating the fifth electrode and the third gate from each other; and
a third doped region of the second conductivity type in the semiconductor material layer, wherein the third doped region is between the first trench structure and the third trench structure, and the first trench structure is located between the first doped region and the third doped region.

7. The trench semiconductor structure of claim 6, further comprising:
a fourth conductive plug at least partially surrounded by the third doped region and electrically connected to the metal layer.

8. The trench semiconductor structure of claim 1, wherein the first oxide layer located between the first electrode and the semiconductor material layer has a first thickness, the first oxide layer located between the first gate and the semiconductor material layer has a second thickness, and the second thickness is greater than the first thickness.

9. The trench semiconductor structure of claim 1, further comprising:
a fourth oxide layer located on the first surface of the semiconductor material layer and between the interlayer dielectric layer and the first surface.

10. A trench semiconductor structure, comprising:
a semiconductor material layer of a first conductivity type, having a first region and a second region surrounding the first region;
a first trench structure, recessed from a first surface of the semiconductor material layer into the semiconductor material layer, and comprising a first electrode, a first gate, and a first oxide layer surrounding and separating the first electrode and the first gate;
a second trench structure, recessed from the first surface of the semiconductor material layer into the semiconductor material layer, and comprising a second electrode, a second gate, and a second oxide layer surrounding and separating the second electrode and the second gate; and
a first doped region of a second conductivity type, disposed in the semiconductor material layer and between the first trench structure and the second trench structure; and
wherein the first electrode and the second electrode are disposed between the first gate and the second gate,
the first electrode, the second electrode, and the first doped region between the first electrode and the second electrode are located in the first region, and
the first gate and the second gate are located in the second region.

11. The trench semiconductor structure of claim 10, wherein the first region comprises a super barrier rectifier (SBR) including the first electrode, the second electrode and the first doped region, and the second region comprises a shielded gate trench metal oxide semiconductor field effect transistor (SGT MOSFET).

12. The trench semiconductor structure of claim 10, wherein the first trench structure further includes a third electrode, at least a portion of the first gate is located between the first electrode and the third electrode, and the first oxide layer surrounds and separates the first electrode, the third electrode and the first gate.

13. The trench semiconductor structure of claim 12, wherein the semiconductor material layer has a third region adjacent to the second region and different from the first region, and the third electrode is located in the third region.

14. The trench semiconductor structure of claim 10, wherein a length of the first electrode is same as or different from a length of the second electrode in a top view of the trench semiconductor structure.

15. A method of manufacturing a trench semiconductor structure, comprising:
forming a first trench in a semiconductor material layer of a first conductivity type, wherein the first trench extends from a first surface of the semiconductor material layer toward a second surface of the semiconductor material layer opposite to the first surface;
forming, in the first trench, a first electrode, a second electrode and a first gate, wherein the first gate and the first electrode are formed above the second electrode, and the first electrode, the second electrode and the first gate form a first trench structure;
forming a first doped region of a second conductivity type in the semiconductor material layer, wherein the first electrode is located between the first doped region and the first gate;
forming a second doped region of the first conductivity type in the first doped region and adjacent to the first surface of the semiconductor material layer, the second doped region being a heavily doped region;
forming an interlayer dielectric layer over the first surface of the semiconductor material layer, wherein the interlayer dielectric layer covers the first trench structure and the second doped region; and
forming a metal layer on the interlayer dielectric layer,
wherein the first electrode and the first doped region are electrically connected to the metal layer.

16. The method of claim 15, further comprising:
forming a first conductive plug extending from the metal layer through the interlayer dielectric layer and contacting the first electrode; and
forming a second conductive plug extending from the metal layer through the interlayer dielectric layer and the second doped region, and contacting the first doped region.

17. The method of claim 15, further comprising:
forming a second trench in the semiconductor material layer extending from the first surface toward the second surface;
forming, in the second trench, a third electrode, a fourth electrode and a second gate, wherein the second gate and the third electrode are formed above the fourth electrode, and the third electrode, the fourth electrode and the second gate form a second trench structure; and
forming a third conductive plug extending from the metal layer through the interlayer dielectric layer and contacting the third electrode,
wherein the first doped region is between the first trench structure and the second trench structure, and the interlayer dielectric layer covers the second trench structure.

18. The method of claim 17, further comprising:
forming a first oxide layer in the first trench surrounding and separating the first electrode, the second electrode and the first gate; and
forming a second oxide layer in the second trench surrounding and separating the third electrode, the fourth electrode and the second gate.

19. The method of claim 17, further comprising:
forming a third trench in the semiconductor material layer, the third trench extending from the first surface toward the second surface, and the first trench being located between the third trench and the second trench; and
forming a fifth electrode, a third gate over the fifth electrode, and a third oxide layer surrounding and separating the fifth electrode and the third gate,
wherein the fifth electrode, the third gate and the third oxide layer form a third trench structure, and the first trench structure is located between the second trench structure and the third trench structure.

20. The method of claim 15, further comprising:
forming a third doped region of the second conductivity type in the semiconductor material layer, wherein the first gate is located between the third doped region and the first electrode;
forming a fourth doped region in the third doped region adjacent to the first surface of the semiconductor material layer, wherein the fourth doped region is a heavily doped region of the first conductivity type; and
forming a fourth conductive plug b extending through the fourth doped region from the metal layer, and contacting the third doped region.
